(19) United States
(12) Patent Application Publication
(10) Pub. No.: US 2024/0029963 A1
(43) Pub. Date: Jan. 25, 2024

(54) AMPHIPHILIC CO-POLYMER LIPID PARTICLES, METHODS OF MAKING SAME, AND PHOTO-ELECTRICAL ENERGY GENERATING DEVICES INCORPORATING SAME

(71) Applicant: UNIVERSITY OF TENNESSEE RESEARCH FOUNDATION, Knoxville, TN (US)

(72) Inventors: Nathan G. BRADY, Knoxville, TN (US); Barry D. BRUCE, Knoxville, TN (US)

(73) Assignee: UNIVERSITY OF TENNESSEE RESEARCH FOUNDATION, Knoxville, TN (US)

(21) Appl. No.: 18/449,245

(22) Filed: Aug. 14, 2023

Related U.S. Application Data
(62) Division of application No. 17/594,503, filed on Oct. 20, 2021.
(60) Provisional application No. 62/836,671, filed on Apr. 21, 2019.

(51) Int. Cl. H01G 9/20; H10K 71/12; H10K 85/00

(52) U.S. Cl. CPC H01G 9/2059; H01G 9/2027; H10K 71/12; H10K 85/761

(57) ABSTRACT

Amphiphilic co-polymer lipid particle has a core comprising a chlorophyll pigment-protein complex or a bacteriochlorophyll pigment-protein complex within an annulus of membrane lipids, and an outermost layer of amphiphilic co-polymer surrounding an outermost surface of the membrane lipids. Such lipid particles are made by isolating photosynthetic membrane to form isolated photosynthetic membrane, adjusting the chlorophyll concentration of the isolated photosynthetic membrane, and solubilizing the isolated photosynthetic membranes in an amphiphilic co-polymer for a preselected time period that allows amphiphilic co-polymer lipid particles to form. The amphiphilic co-polymer lipid particles form a layer between a cathode and an anode in a photo-electrical energy generating device, and methods of making the same, including a layer of detergent micelles encapsulating lipid proteins rather than amphiphilic co-polymer lipid particles.

### RELATED APPLICATIONS

This application is a divisional of U.S. application Ser. No. 17/594,503, filed Oct. 20, 2021, which was the National Stage of International Application No. PCT/US2020/029054, filed Apr. 21, 2020, which claims the benefit of U.S. Provisional Application No. 62/836,671, filed Apr. 21, 2019.

### FIELD OF THE INVENTION

The present invention relates generally to amphiphilic co-polymer lipid particles, and more particularly to styrene maleic acid lipid particles that have a core of a chlorophyll pigment-protein complex or a bacteriochlorophyll pigment-protein complex within an annulus of membrane lipids and an outermost layer of the amphiphilic co-polymer, methods of making the same, and photo-electrical energy generating devices incorporating the same.

### BACKGROUND OF THE INVENTION

With the sequencing of thousands of prokaryotic and eukaryotic genomes it is now clear that integral membrane proteins comprise ˜30% of the proteins encoded in those genomes. Although this advance in genome science has been concurrent with the rapid increase of new high resolution crystal structures, only ˜3% of all the structures deposited in the PDB represent membrane proteins. This lag between genetic advances and the structural understanding of membrane proteins is due in large part to the challenges of expression, purification, and crystallization of membrane proteins. Traditionally membrane proteins have been isolated following solubilization with non-ionic detergents, which involves detergent insertion into the membrane exchanging with native lipids, where at high detergent levels a mixed micelle is formed containing the membrane protein(s) surrounded by detergents and remaining lipids. This approach has led to a plethora of new detergent classes, yet a slow and systematic approach is still required to determine the best means of solubilizing, stabilizing and structurally characterizing active membrane proteins. This requires an empirical approach to optimize detergent selection, and greatly obstructs efforts to understand the structure and function of membrane proteins.

Recently there have been many reports on non-detergent methods of membrane protein isolation. These include various peptide-based nanodiscs, utilizing amphipathic helical membrane scaffold proteins (MSPs), for individual proteins as well as whole proteomes. Most of these advances have required initial detergent solubilization followed by the addition of phospholipids and MSPs. The membrane protein(s) will self-assemble into nanodiscs when the detergent is removed. A recent investigation showed that a new strategy termed “nanodisc-reconstitution before purification” resulted in a close to completely assembled vacuolar ATPase from yeast with high activity. These peptide-based nanodiscs were made up of native membrane lipids, however in this approach the degree to which leaflet heterogeneity of the native lipids, as well as the specific composition of lipids that interface with the isolated membrane protein is unknown. We have theorized that the native lipid environment is critical to the overall function of membrane proteins and herein show that the initial detergent solubilization step prior to insertion into MSP-based nanodiscs cannot be avoided.

Membrane protein research has shown the ability of styrene maleic acid (SMA) alternating copolymers to solubilize membranes in the form of nanodiscs, allowing extraction and purification of membrane proteins from their native environment in a single detergent-free step. SMA solubilization has three major advantages over MSP nanodiscs or other detergent-dependent isolations: 1) permits direct solubilization and purification of membrane proteins while maintaining their lipid environment; 2) avoids the empirical and laborious detergent-based procedures and their inherent risk of protein aggregation and/or denaturation; and 3) SMALPs provide a stable lipid environment for membrane proteins with small particle size, compatible with a wide range of biophysical approaches. This has important implications for membrane biology in part because it allows for the isolation and characterization of both membrane proteins and their boundary lipids in a near-native environment.

Recently in the field of bioenergetics, two of the most well characterized classes of membrane proteins, the purple bacterial photosynthetic reaction centers and the plant PSI-LHCII supercomplex, have been characterized using SMA isolation. In the latter study, the authors report PSI-LHCII super complex was not encapsulated within a SMALP, rather the spinach thylakoid membrane fraction that remained following incubation with SMA was highly enriched in PSI-LHCII super complexes. This membrane pellet was also depleted is PSII (alone), the cytochrome b₆f complex and CF₁-CF₀ (of the ATPase). This highly ordered region of plant thylakoids was described as being analogous to BBY preparation in spinach thylakoid membranes. This protocol utilizes the lateral heterogeneity of plant thylakoids to separate the PSII-rich stacked thylakoids and the non-stacked stromal lamellae, which contains less PSII.

The exact reason for this apparent selectivity for SMA is unknown, however we can reason that this is either due to an unforeseen preference for particular SMA formulations to make SMALPs of a specific size range, or more likely that the isolated proteins are enriched in a particular region of the thylakoid membrane, and this region is more permissible for SMA insertion. The latter hypothesis is further supported in cyanobacteria as well, with two recent atomic force microscopy studies that show regions of the thylakoid membrane in Te and Prochlorococcus indeed show this lateral heterogeneity, revealing that PSI trimers exist in a nearly ordered hexagonal array in parts of the thylakoid. The reason why these regions are more prone to SMA solubilization remains to be elucidated, however it is logical to assert that if the proteins are laterally heterogeneous, the lipids surrounding them may be as well, affording the possibility of lipid specificity for SMA insertion.

Photosystem I (PSI) is a membrane-spanning protein complex that contains 12 individual subunits and ca. 120 cofactors. PSI is one of the key enzymes of the photosynthetic electron transfer chain, which catalyzes the light-driven one-electron transfer from peripheral protein donor, plastocyanin, and/or cytochrome c₆, to ferredoxin and/or flavodoxin. The crystallographic structure of Thermosynechococcus elongatus PSI complexes with a resolution of 2.5 Å led to an accurate model for the architecture of proteins, cofactors and pigments in that system. Cyanobacterial PSI assembles into a trimer with a C3 axis of symmetry. Each complex, in turn, is a heterodimer formed by symmetrically- and homology-related core subunits, PsaA and B. This geometry leaves both the C3 and C2 symmetry axis perpendicular to the membrane plane, with the C2 axis passing through a special dimer of P₇₀₀ chlorophyll (Chl) on the donor side and through an iron-sulfur cluster Fₓ on the acceptor side. All redox cofactors, except terminal iron-sulfur clusters F_{A}/F_{B} are located within PsaA/PsaB core subunits in a pseudosymmetrical manner and form two (A and B) branches for potential electron transfer. The two cofactor branches of the electron transfer chain merge onto the inter-polypeptide iron-sulfur cluster Fₓ. The two terminal electron acceptors F_{A} and F_{B} are [4Fe-4S] clusters located on the stromal surface coordinated via the subunit PsaC. In addition, PSI also coordinates 96 Chl a molecules and 22 molecules of β-carotene, which serve as antenna pigments. In contrast to the bacterial and photosystem II (PSII) reaction center (RC) complexes, the structure of PSI make it impossible to biochemically separate the Chl molecules associated with PSI RC from those functioning as light-harvesting chlorophyll.

Recently the energy- and electron-transfer reactions in PSI have been studied using various ultrafast techniques, including pump-probe absorption spectroscopy. However, to date, the kinetics of the primary charge separation in PSI remain controversial. Thus, after absorption of light by integral antenna pigments, the excitation energy is efficiently transferred to a RC where the light-induced charge separation into an ion-radical pair between a special pair of Chl, P₇₀₀, and the primary electron acceptor A₀ occur. The electron from accessory chlorophyll A₀ is further transferred to the phylloquinone (Ai) and finally to the F_{A}/F_{B} via inter-protein iron-sulfur cluster Fₓ. Most of the previous studies put the primary charge separation step from P₇₀₀*to A₀ in PSI RC in the 0.8-4 ps time range, and the subsequent electron transfer from primary electron acceptor A₀ to the secondary electron acceptor Ai was suggested to occur in 10-50 ps range. However, a number of studies have shown that in purified PSI complexes from cyanobacteria Synechocystis sp. PCC 6803 after preferential excitation of P₇₀₀ and A₀, formation of primary radical pair P₇₀₀⁺A₀⁻ occurs, within 100 fs, and the formation of P₇₀₀⁺A₁⁻ has a characteristic time of ˜25 ps.

Energy transfer processes between the light-harvesting antenna chlorophylls and the special pair of chlorophyll P₇₀₀ of the PSI RC have been the subject of many years of research. In the simplest version, the kinetic scheme of the energy transfer processes and the charge separation reactions in RC can be represented by Scheme 1 in FIG. 14.

The organization of pigments within protein complex provides for an effective energy transfer in the antenna and delivery of the excitation energy to the RC where the charge separation takes place. The efficiency of energy transfer through the system of exciton-coupled cofactors is controlled by their spatial organization (distances between pigments and angles between the dipole transition vectors), as well as by the excitation energies of the lowest Q_{Y} electronic transition of chlorophyll. The electron donor in PSI is a special pair of Chl molecules, P₇₀₀, whose Q_{Y} band has a maximum near 700 nm at the red edge of the PSI absorption spectrum. In antenna of many cyanobacteria, there are long-wavelength forms of chlorophyll (LWC), which absorb in the far-red edge of spectrum below the P₇₀₀ special pair. In PSI from T. elongatus, three LWC forms C-708, C-715 and C-719 were detected.

Generally, the photochemical production of the oxidized special pair (P₇₀₀+) may occur by three alternative pathways. The first path is via the direct excitation of the special pair (dashed arrow (1) in FIG. 14). In PSI complexes from Synechocystis sp. PCC 6803, which contain a minimal number of LWC forms, an ultra-fast formation of the ion-radical state (P₇₀₀A₀)*→P₇₀₀⁺A₀⁻ was revealed upon excitation in the far-red region, so the assessed life-time of ˜100 fs may be considered as an estimation of the respective rate constant m₁=10¹³ s⁻¹.

The second route to charge separation entails the migration of energy from LWC to the RC (dotted arrow (2) in FIG. 14). When following uphill via the excited state (P₇₀₀A₀)*, this process requires an activation energy of ˜50 meV. In PSI complexes from Chroococcidiopsis thermalis PCC 7203 the energy transfer occurred at 97 ps, so the assessed rate constant of excitation migration from the LWC to P₇₀₀, k₃=10¹⁰ s⁻¹, was slower than the rate of the secondary electron transfer reaction m₂=4×10¹⁰s⁻¹. Further, a slow charge separation was observed at cryogenic temperatures in PSI from Thermosynechococcus elongatus and Arthrospira platensis, indicating the possibility of a direct, activation-less transition from the excited LWC to a suggested charge transfer (CT) state via a superexchange mechanism (the rate constant m₀) similar to the mechanism proposed for purple bacteria. Lastly, energy absorbed by the high energy chlorophyll in antenna (An*) can migrate to the LWC in the time range of few picoseconds, so the effective rate constant k₁ has magnitude of 3×10¹¹ s⁻¹. In addition, a direct pathway of energy transfer from An* to P₇₀₀ (the rate constant k₂) might be considered as a potential alternative.

The LWC molecules operate as energy traps, because the ratio of the forward and backward rate constants of energy transfer between chlorophyll molecules 1 and 2 obeys the Boltzmann distribution k₁₂/k₂₁=exp(−ΔF₁₂/k_{B}T), where ΔE₁₂=E₂−E₁ is the difference between the energies of their excited states. For this reason, the disturbance of the native conformation of PSI during isolation procedure can significantly affect the energy transfer dynamics and charge separation kinetics. In isolated cyanobacterial PSI complexes detergents can destroy a two-layer structure and form micellar structures around the hydrophobic transmembrane regions of the protein. While this approach has yielded many results in the detergent solubilized state, membrane proteins tend to have limited stability and often exhibit much reduced activity when compared with native forms.

Thus, there is a need to solubilize lipid proteins with an efficient extraction yield without denaturing the protein, in a detergent-less solubilization process, that can preserve or maintain the energy transfer and charge transfer process of the pigment protein complexes. As such, the pigment protein complexes will have electrons available for photo-electrical energy generation making the pigment protein complexes suitable for use in photo-electrical energy generating devices.

### SUMMARY

In all aspects, amphiphilic co-polymer lipid particles are disclosed that have a core of a chlorophyll pigment-protein complex or a bacteriochlorophyll pigment-protein complex within an annulus of membrane lipids, and an outermost layer of amphiphilic co-polymer surrounding an outermost surface of the membrane lipids. The chlorophyll pigment-protein complex or bacteriochlorophyll pigment-protein complex are from a chloroplast of a plant or algae, or from a photosynthetic bacterium or a cyanobacteria and comprise a photosystem I complex, a photosystem II complex, or combinations thereof. When the photosystem I complex is present, the particles are disc-shaped nanoparticles.

In all aspects, the amphiphilic co-polymer has a hydrophobic portion selected from styrene or diisobutylene and a hydrophilic portion selected from maleic acid, carboxyl amide, or maleimide. The maleic acid can be esterified with an alkoxy functional group selected from methoxy, ethoxy, propoxy, butoxy, pentoxy, hexoxy, and combinations thereof. In one embodiment, the amphiphilic co-polymer is styrene maleic acid. In other embodiment, the amphiphilic co-polymer is diisobutylene maleic acid or styrene maleimide.

In all aspects, methods for making amphiphilic co-polymer lipid particles are disclosed that include isolating photosynthetic membrane to form isolated photosynthetic membrane, adjusting the chlorophyll concentration of the isolated photosynthetic membrane; and solubilizing the isolated photosynthetic membranes in an amphiphilic co-polymer for a preselected time period that allows amphiphilic co-polymer lipid particles to form. The time period is 1 hour to 12 hours. The amphiphilic co-polymer can be any of those disclosed herein.

Solubilizing the isolated photosynthetic membrane includes maintaining the pH in the range of equal to or greater than 8.5 but equal to or less than 10.5, adjusting a solubilizing temperature to a range of about 4° C. to 60° C., and/or adding 25 mM to 500 mM of monovalent cations.

Adjusting the chlorophyll concentration comprises normalizing the chlorophyll concentration to a value within a range of 0.5 mg/mL to 1.5 mg/mL.

In all aspects, photo-electrical energy generating devices are disclosed that have a first electrode layer defining a first major surface and an opposing major surface with a photoactive layer in direct contact with the first electrode layer. The photoactive layer has amphiphilic co-polymer lipid particles as described herein or detergent micelle encapsulated lipid proteins. A second electrode layer is present and is in electrical communication with the first electrode layer. In one embodiment, the device is a dye-sensitized energy generating device and the first electrode is an anode. The amphiphilic co-polymer lipid particles or the detergent micelle encapsulated lipid proteins are mixed with a metal oxide. The metal oxide is selected from the group consisting of titanium dioxide, zirconium dioxide, nickel oxide, zinc oxide, tin oxide, tungsten trioxide, alumina, and combinations thereof.

In another embodiment, the first electrode is a cathode and the device is a solid state device. Here, a layer of metal oxide particles is in direct contact with the photoactive layer opposite the cathode, and the second electrode is an anode, which is in direct contact with the layer of metal oxide particles opposite the photoactive layer. The cathode can be a P- or N-doped silicon electrode and the anode is a transparent conductive electrode, such as an indium doped tin oxide electrode or a fluorine doped tin oxide electrode.

In all aspect, methods for making a photo-electrical energy generating device are disclosed that include providing a first electrode layer, the first electrode layer having a first major surface opposing a second major surface, drop-casting a photoactive layer comprising amphiphilic co-polymer lipid particles or detergent micelles encapsulating lipid proteins onto the first major surface of the first electrode layer and drying under vacuum, subsequently, drop-casting a semiconductor or conductive layer onto the photoactive layer and drying under vacuum, and placing a second electrode layer in direct contact with the semiconductor layer. The amphiphilic co-polymer lipid particles and the detergent micelles encapsulating lipid proteins are any of those described herein. The layers can be sandwiched between transparent outermost layers.

The conductive layer can comprise carbon, such as graphene or carbon nanostructures, platinum metal, silver metal, and combinations thereof. The semiconductor layer comprises a metal oxide selected from the group consisting of titanium dioxide, zirconium dioxide, nickel oxide, zinc oxide, tin oxide, tungsten trioxide, alumina, and combinations thereof.

These and other aspects, objects, features and advantages of the example embodiments will become apparent to those having ordinary skill in the art upon consideration of the following detailed description of illustrated example embodiments.

### BRIEF DESCRIPTION OF THE DRAWINGS

FIG. 1 is a representation of a styrene maleic acid lipid particle.

FIG. 2 is a top view representation of a detergent micelle enclosing a pigment protein and membrane lipids.

FIG. 3 is a top view representation of the styrene maleic acid lipid particle of FIG. 1.

FIG. 4 is a chart of sample styrene maleic acid copolymers and data for the same.

FIG. 5A is a photograph of BN-PAGE gel analysis of PSI within DDM micelle and SMALP over a range of concentrations.

FIG. 5B is a photograph of BN-PAGE gel analysis of PSI within SMALP over a pH range.

FIG. 5C is a photograph of BN-PAGE gel analysis of PSI within SMALP of increasing concentration at different temperatures.

FIGS. 5D-F are photographs of BN-PAGE gel analysis of PSI within SMALP in the presence of increasing concentrations of different salts.

FIG. 6A is a photograph of BN-PAGE gel analysis of PSI and PSII oligomers encapsulated within DDM micelles and SMALPs showing a full protein profile.

FIG. 6B is a graph of the relative mobility and apparent molecular weight of the PSI-SMALP as determined by linear regression of the molecular weight standards from FIG. 6A.

FIG. 7 is a photograph of bands of pigments and pigment protein complexes separated via sucrose density gradient ultracentrifugation.

FIG. 8 is a graph of a low temperature fluorescence spectrum of the trimeric PSI encapsulated within SMALP and DDM micelles isolated from band 3 of FIG. 7.

FIG. 9 is a photograph of silver staining of SDS-PAGE of the PSI extracted from SMALP compared to a DDM micelle and a standard.

FIG. 10 is a photograph of an immunoblot analysis probing for PsaF subunit from PSI, transferred from a SDS-PAGE analysis of Chroococcidiopsis sp TS-821 for comparison to a Te SMALP and a DDM micelle.

FIG. 11A is a graph of photochemical activity from P700 photooxidation and reduction by cytochrome c6 soluble electron carrier of a PSI-SMALP at selected ratios of Cyt:PSI.

FIG. 11B is a graph of photochemical activity from P700 photooxidation and reduction by cytochrome c6 soluble electron carrier of PSI-DDM in the SMA buffer at selected ratios of Cyt:PSI.

FIG. 11C is a graph of photochemical activity from P700 photooxidation and reduction by cytochrome c6 soluble electron carrier of PSI-DDM in the DDM buffer at selected ratios of Cyt:PSI.

FIG. 11D is a graph of the observed reduction rate constant from single experimental decay curves plotted against molar ratio of cytochrome c6 for the samples of FIGS. 11A-11C.

FIG. 11E is a graph of P700 reduction curves for PSI-DDM and PSI-SMALP using horse heart cytochrome at 50:1 and 100:1.

FIG. 11F is a bar graph of observed P700 reduction of PSI-DDM and PSI-SMALP with the horse heart cytochrome.

FIG. 12 comprises sedimentation coefficient data for PSI-DDM and PSI-SMALP.

FIG. 13A is a schematic illustration of a model for PSI trimer formation.

FIG. 13B is a schematic illustration of a model from PSI trimer to SMALP

formation.

FIG. 14 is a schematic representation of energy transfer and charge separation reactions for a photosystem I reaction center complexes.

FIG. 15A comprises an exponential deconvolution graphs of the transient spectral dynamics of PSI for PSI-DDM micelle at 740 nm.

FIG. 15B comprises an exponential deconvolution graph of the transient spectral dynamics of PSI for PSI-SMALP micelle at 740 nm.

FIG. 15C comprises an exponential deconvolution graph of the transient spectral dynamics of PSI for PSI-DDM micelle at 670 nm.

FIG. 16 comprises Graph A and B of the contribution of the ionic state to the spectral dynamics of PSI-DDM and PSI-SMALP complexes from T. elongates excited by a long-wave pulse of 740 nm.

FIG. 17 is a longitudinal cross-sectional representation of the layers of a biohybrid solid state device having a photoactive layer comprising PSI-DDM micelles or PSI-SMALPs.

FIG. 18 is a representation of a dye sensitized solar cell modified to have a layer that includes PSI-SMALP nanodiscs.

FIG. 19 is a representation of an electrode with a titanium dioxide layer and a layer of PSI-SMALP nanodiscs for inclusion in a solar cell, such as the dye sensitized solar cell of FIG. 22.

FIG. 20 is a graph of the photocurrent of a solar cell having the construction of FIG. 21 over 40 seconds.

FIG. 21 is a graph of the photocurrent of a solar cell having the construction of FIG. 21 over 300 seconds.

FIG. 22 is a graph comparing the photocurrent of a solar cell having the construction of FIG. 21 with a solar cell comprising PSI-DDM micelles or PSI-SMALP.

FIG. 23 is a graph comparing the photovoltage of a solar cell having the construction of FIG. 21 with a solar cell comprising PSI-DDM micelles or PSI-SMALP.

### DETAILED DESCRIPTION

The following description and drawings are illustrative and are not to be construed as limiting. Numerous specific details are described to provide a thorough understanding of the disclosure. In certain instances, however, well-known or conventional details are not described to avoid obscuring the description. References to one or an embodiment in the present disclosure can be, but not necessarily, are references to the same embodiment; and, such references mean at least one of the embodiments.

Unless otherwise noted, technical terms are used according to conventional usage. Definitions of common terms in molecular biology may be found in Benjamin Lewin, Genes IX, published by Jones and Bartlet, 2008 (ISBN 0763752223); Kendrew et al. (eds.), The Encyclopedia of Molecular Biology, published by Blackwell Science Ltd., 1994 (ISBN 0632021829); and Robert A. Meyers (ed.), Molecular Biology and Biotechnology: a Comprehensive Desk Reference, published by VCH Publishers, Inc., 1995 (ISBN 9780471185710) and other similar references. As used herein, the singular forms “a,” “an,” and “the,” refer to both the singular as well as plural, unless the context clearly indicates otherwise. The abbreviation, “e.g.” is derived from the Latin exempli gratia and is used herein to indicate a non-limiting example. Thus, the abbreviation “e.g.” is synonymous with the term “for example.” As used herein, the term “comprises” means “includes.” All publications, patent applications, patents, and other references mentioned herein are expressly incorporated herein by reference in their entirety.

“Isolated” as used herein refers to biological proteins that are removed from their natural environment and are isolated or separated and are free from other components with which they are naturally associated. The term “purified” does not require absolute purity; rather, it is intended as a relative term. Thus, for example, a purified or “substantially pure” protein preparation is one in which the protein referred to is more pure than the protein in its natural environment within a cell or within a production reaction chamber (as appropriate).

As used herein, relative terms, such as “substantially,” “generally,” “approximately,” “about,” and the like are used herein to represent an inherent degree of uncertainty that can be attributed to any quantitative comparison, value, measurement, or other representation. These terms are also utilized herein to represent the degree by which a quantitative representation can vary from a stated reference without resulting in a change in the basic function of the subject matter at issue. In certain example embodiments, the term “about” is understood as within a range of normal tolerance in the art for a given measurement, for example, such as within 2 standard deviations of the mean. In certain example embodiments, depending on the measurement “about” can be understood as within 10%, 5%, 1%, 0.5%, 0.1%, 0.05%, or 0.01% of the stated value. Unless otherwise clear from context, all numerical values provided herein can be modified by the term about. “Substantially free” or “free” besides the values just stated, can be zero.

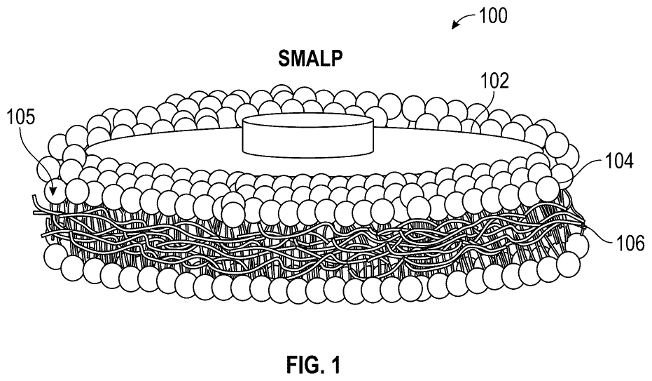

Referring to FIGS. 1 and 3, an amphiphilic co-polymer lipid particle 100 is represented. The amphiphilic co-polymer lipid particle 100 has a core of a chlorophyll pigment-protein complex or a bacteriochlorophyll pigment-protein complex 102 within an annulus of membrane lipids 104 and an outermost layer 105 of amphiphilic co-polymer 106 surrounding the membrane lipids 104. The amphiphilic co-polymer 106 in FIG. 1 is a plurality of SMA fragments wrapped about a centroid of the outermost surface of the membrane lipids 104. The outermost layer of amphiphilic co-polymer 105 is likely intercalated into the acyl region of the membrane lipids 104 and is occluding the hydrophobic interior of the membrane from solvent.

The chlorophyll pigment-protein complex or bacteriochlorophyll pigment-protein complex are from a chloroplast of a plant or algae, or from photosynthetic bacterium or cyanobacteria. Any plant or algae having chloroplasts is possible. One non-limiting example that was tested is spinach, i.e., Spinacea oleracea. Any cyanobacteria is possible. Two non-limiting examples that were tested include Thermosynechococcus elongatus (Te) and Chroococcidiopsis sp TS-821, which are thermophilic cyanobacteria. The chlorophyll- or bacteriochlorophyll-pigment proteins complexes comprise a photosystem I protein, a photosystem II protein, or combinations thereof.

The amphiphilic co-polymer has a hydrophobic portion selected from styrene or diisobutylene and a hydrophilic portion selected from maleic acid, carboxyl amide, or maleimide. As discussed above, with respect to FIG. 1, the amphiphilic co-polymer can be styrene maleic acid. In another embodiment, the amphiphilic co-polymer can be diisobutylene maleic acid, styrene carboxyl amide, styrene maleimide, diisobutylene carboxyl amide, or diisobutylene maleimide. [I listed all possible combinations, verify for accuracy.]

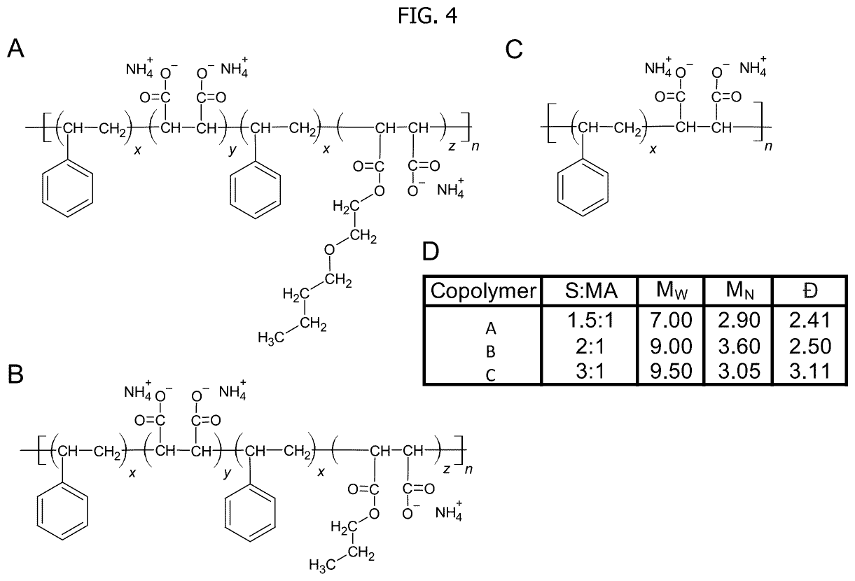

When maleic acid is present, it can be esterified with an alkoxy functional group. The alkoxy functional group may be methoxy, ethoxy, propoxy, butoxy, pentoxy, hexoxy, and combinations thereof. Referring now to FIG. 4, in a first embodiment, chemical formula A, the SMA is functionalized with a butoxyethanol group, and in a second embodiment, chemical formula B, the SMA is functionalized with a propanol group. The chemical formula C is an SMA without an alkoxy chain added to the backbone. Chart D in FIG. 4 lists some characteristics of the SMAs A-C, in particular, the difference in styrene to maleic acid ratio (S:MA), number weighted molecular weight (M_{N}), weight weighted molecular weight (M_{W}), and dispersity (Ð), which is the quotient of M_{W}/M_{N}. SMA copolymers were acquired from TOTAL Cray Valley USA, LLC. In FIG. 4, SMA of chemical formula A is SMA 1440, SMA of chemical formula B is SMA 2525 and SMA of chemical formula C is SMA 3000 from Cray Valley USA, LLC.

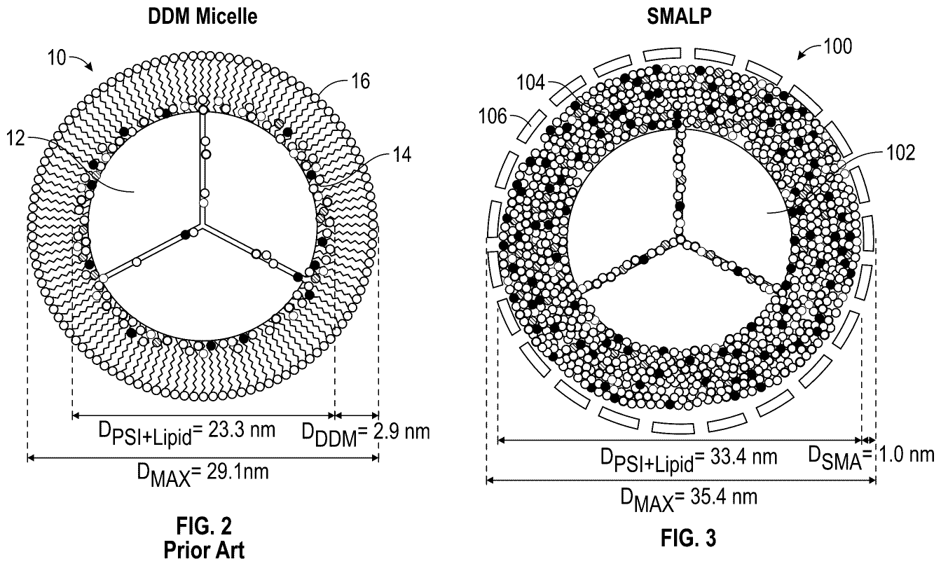

Still referring to FIGS. 1 and 3, when the solubilized lipid proteins are photosystem I proteins, the amphiphilic co-polymer lipid particles are disc-shaped nanoparticles. Each disc-shaped nanoparticle has an average mean diameter of about 35 nm and an average mean mass of about 1.5 MDa. Since SMA is the amphiphilic co-polymer in this example, the nanoparticle is referred to as a SMA lipid particle or “SMALP.” This particular photosystem I protein has been characterized as have 36 protein subunits, over 380 non-covalently bound cofactors and a molecular weight of about 1.2 MDa. In comparison, FIG. 2, a micelle enclosing the same PSI protein in the non-ionic detergent n-dodecyl-β-D-maltoside (DDM) is smaller in diameter. The SMALP has a fundamentally different structure than the DMM micelle. Further differences between the SMALP and the DDM micelle are set forth in the working examples and comparative analysis set forth below.

Methods for making amphiphilic co-polymer lipid particles include isolating photosynthetic membrane to form isolated photosynthetic membrane, adjusting the chlorophyll concentration of the isolated photosynthetic membrane, and solubilizing the isolated photosynthetic membrane in an amphiphilic co-polymer for a preselected time period that allows amphiphilic co-polymer lipid particles to form. The preselected time period is 1 hour to 12 hours. The photosynthetic membrane and the amphiphilic co-polymer is any of those discussed above for the amphiphilic co-polymer lipid particle. Depending upon the amphiphilic copolymer selected, the conditions, of pH, temperature, monovalent cation concentration, and temperature may vary.

Isolating the photosynthetic membrane includes providing a source of chloroplast of a plant or algae, or from photosynthetic bacteria or cyanobacteria, culturing and harvesting cells according to know procedures including those disclosed in Sakthivel et al., A small heat-shock protein confers stress tolerance and stabilizes thylakoid membrane proteins in cyanobacteria under oxidative stress, Arch Microbiol 2009, 191 (4), 319-28.

Solubilizing the isolated photosynthetic membrane when using SMA includes maintaining the pH in the range of equal to or greater than 8.5 but equal to or less than 10.5, adjusting a solubilizing temperature to a range of about 4° C. to 60° C., adding 25 mM to 500 mM of monovalent cations.

Adjusting the chlorophyll concentration includes normalizing the chlorophyll concentration to a value within a range of 0.5 mg/mL to 1.5 mg/mL.

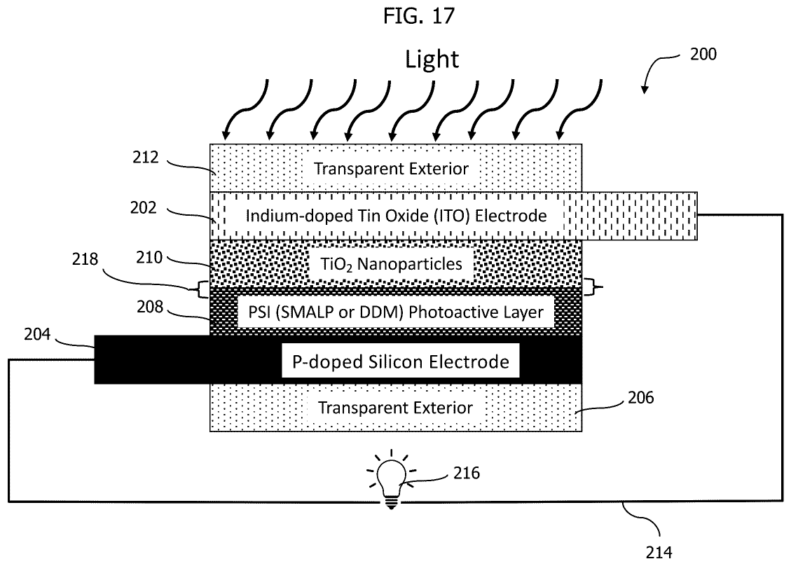

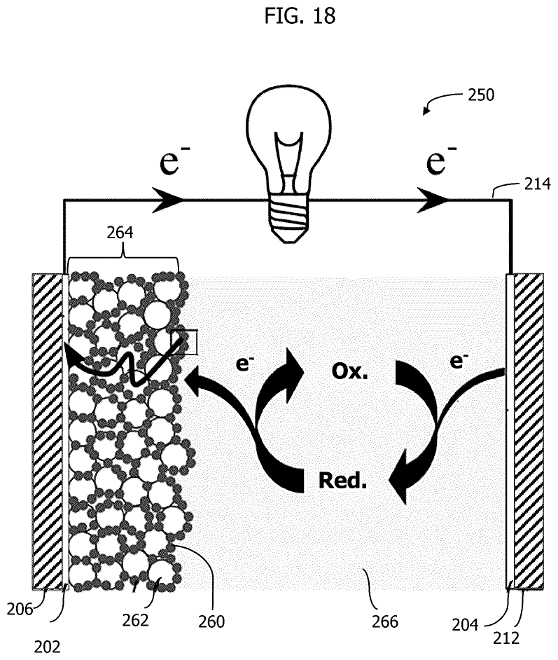

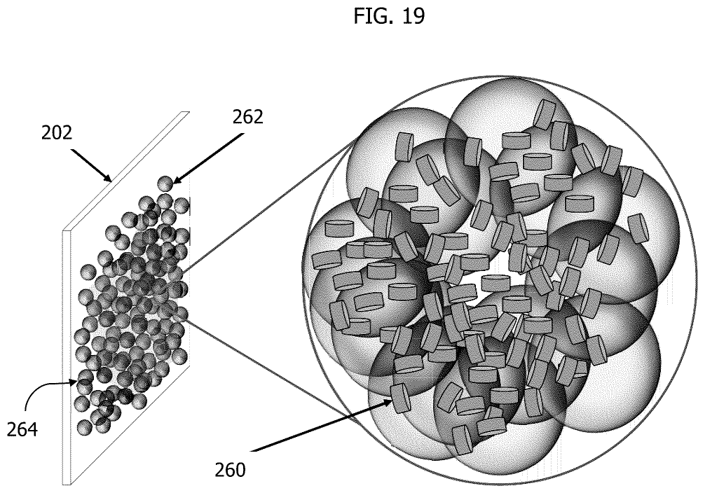

Turning now to FIGS. 17 and 18, photo-electrical energy generating devices 200, 250 are illustrated that have amphiphilic co-polymer lipids particles or detergent micelle encapsulated lipid proteins, present between an anode 202 and a cathode 204. With the presence of the amphiphilic co-polymer lipid particles or detergent micelle encapsulated lipid proteins, these may be referred to as biohybrid devices, which utilize light energy applied photosynthetic systems to generate electrical energy.

In FIG. 17, the solar cell 200 has an outermost transparent substrate 206 upon which the cathode 204 is layered in direct contact therewith. A layer of PSI-SMALPs or PSI-DDM form a photoactive layer 208, which is in direct contact with the cathode 204 opposite the transparent substrate 206. A semiconductor layer 210, which may comprise metal oxide nanoparticles or an equivalent substitute for metal oxide, is in direct contact with the photoactive layer 208 opposite the cathode 204. The anode 202 is in direct contact with the layer of metal oxide nanoparticles 210 opposite the layer of SMALPs. And, an outermost transparent covering 212 is in direct contact with the anode 202 opposite the layer of metal oxide nanoparticles 210. As such, the layered-up structure in order from backside to topside comprises: transparent substrate 206; cathode 204; photoactive layer 208; layer of metal oxide nanoparticles 210; anode 202, and transparent covering 212. Each layer is present on a major surface of its immediately neighboring layer.

The anode 202 and the cathode 204 are in electrical communication with one another by electrical connector 214, such as a wire. The electrical connector 214 can also connect the biohybrid device 200 to a device in need of electrical power 216, represented in the figure as a light bulb.

The device of FIG. 17 can be made by providing a first electrode layer 204, such as a cathode layer, which has a first major surface opposing a second major surface, and drop-casting a photoactive layer 208 comprising the amphiphilic co-polymer lipid particles or detergent micelle encapsulated lipid proteins on to the first major surface of the first electrode layer 204 and drying the same under vacuum, and then, drop-casting a semiconductor layer or a conductor layer on to the photoactive layer 208 and drying under vacuum. This method results in an intermixed boundary layer 218 at the interface of the photoactive layer 208 to the semiconductor layer or conductor layer 210. Then, a second electrode layer 202, such as an anode layer, is placed in direct contact with the semiconductor layer or a conductor layer 210. This structure is then sandwiched between transparent outermost layers 206, 212, e.g., the layers are under mechanical compression between the transparent outermost layers. During formation one of the transparent outermost layers 206 may be placed in the position of a substrate and upon this substrate, the first electrode layer 204 is seated or layered in direct contact therewith. Then, the above drop-casting occurs. Following the drop-casting of the two layers, the outermost top covering 212 is placed on the semiconductor layer or a conductor layer 210.

The first and second electrodes 202, 204 are not distinguished as an anode or a cathode because the photoactive layer 208 may act as an electron donor or as a hole acceptor, thereby changing whether the first electrode 204 is acting as an anode or a cathode in the particular biohybrid device.

Each method includes electrically connecting the anode to the cathode, which may be by a wire. The amphiphilic co-polymer lipid particles in the devices are any of those described herein

Turning now to FIG. 18, in one embodiment, a SMALP-sensitized biohybrid solar cell 250 is shown that includes amphiphilic co-polymer lipid particles 260 mixed with a metal oxide 262, which forms a layer 264 between the anode 202 and the cathode 204.

Here, an electrolyte 266 forms an electrical junction between the layer 264 and the cathode 204, which is in direct contact with the electrolyte 266. The cathode 204 is covered by a transparent covering 212 and the anode 202 is covered by a transparent covering 206. The anode 202 and the cathode 204 are in electrical communication with one another by electrical connector 214, such as a wire. The biohybrid solar cell 250 can be made using conventional methods, but modified to include drop-casting the photoactive layer 264 comprising the amphiphilic co-polymer lipid particles and semiconductor particles on to a first major surface of a first electrode layer and drying the same under vacuum. Alternately, the photoactive layer 264 can be drop-cast as two layers as described above with respect to FIG. 17. The electrolyte layer, following the formation of the layer(s) by drop-casting, is formed in direct contact with whichever drop-cast layer is the outermost layer. Then, the second electrode layer is formed in direct contact with the electrolyte layer and a transparent top covering is seated in direct contact with the second electrode.

The semiconductor particles can include a metal oxide. The metal oxide can be one or more of titanium dioxide, zirconium dioxide, nickel oxide, zinc oxide, tin oxide, tungsten trioxide, alumina. Alternately, the conductor layer can be carbon, such as graphene or carbon nanostructures, platinum, or silver, or combinations thereof.

Still referring to FIGS. 17-19, the anode 202 can be a transparently conductive oxide glass or plastic electrode, such as an indium doped tin oxide electrode or a fluorine doped tin oxide electrode. The cathode can be a transparent conductive electrode, such as an indium doped tin oxide electrode or a fluorine doped tin oxide electrode, a (P or N) doped silicon electrode, a copper electrode, or carbon, which can be in the form of graphene or carbon nanostructures, including but not limited to nanotubes, and nanowires.

The following examples further illustrate the invention but should not be construed as in any way limiting its scope. Considering the present disclosure and the general level of skill in the art, those of skill will appreciate that the following Examples are intended to be exemplary only and that numerous changes, modifications, and alterations can be employed without departing from the scope of the presently disclosed subject matter.

### Working Example 1

Isolation of Photosynthetic Membranes. Te was cultured in a 25 L airlift bioreactor in BG-11 medium at 45° with aeration. The bioreactor incorporated back panel illumination containing 680 nm red light and fill spectrum white light LEDs with a combined irradiance of 50 μmol photons/m²/s. Cells were harvested at late log phase-pelleted at 12,000 g and stored in 80° C. prior to lysis. The cell pellets were resuspended in buffer A (20-50 mM MES-NaOH, pH=6.5, 10 mM CaCl₂, and 10 mM MgCl₂) containing 500 mM sorbitol for membrane isolation and lysed using a French Press. The lysate was spun down at 12,000 g to separate unbroken cells. Thylakoid membranes were pelleted at 180,000 g in a fixed angle rotor for 30 minutes to 1 hour. The pellets were again re-suspended in buffer A containing 12.5% glycerol and stored at −80° C. Chlorophyll concentration was determined as described by Iwamura et al., Improved Methods for Determining Contents of Chlorophyll, Protein, Ribonucleic Acid, and Deoxyribonucleic Acid in Planktonic Populations, Internationale Revue der gesamten Hydrobiologie and Hydrographie 1970, 55 (1), 131-147, which is incorporated herein by reference in its entirety. Thylakoid membranes were washed three times by Dounce homogenization and pelleting at 180,000×g in Buffer A (for DDM isolation). Buffer S (50 mM Tris-C1, pH=9.5 at room temperature) was used for SMA isolation with varied amounts of KCl and NaCl. Following the last wash, the thylakoid membranes were brought up to a chlorophyll concentration of 1 mg/mL in Buffer A with 12.5% (w/v) glycerol prior to all solubilization trials.

Thylakoid membranes for solubilization with SMA followed the same wash protocol, substituting Buffer A for 50 mM Tris-C1, pH −9.5 with 125 mM KCL (at room temperature) (SMA buffer).

Solubilization in SMA. The thylakoid membranes with its adjusted chlorophyll concentration were solubilized in (1) DDM (Glycon) at 0.6% (w/v) at 25° C. for 1 hour without agitation for a comparison sample and (2) SMA at 40° C. for 3 hours with agitation, preferably SMA A from FIG. 4 at 1.7% SMA. Washing and solubilizing steps were carried out in relative darkness for both isolation methods. Insoluble material was removed by centrifugation at 180,000 g for 5 min at 4° C. Supernatants were taken off for analysis by blue native polyacrylamide gel electrophoresis (BN-PAGE) of the isolated chlorophyll- or bacteriochlorophyll-containing pigment protein complexes, which in this example was a photosystem I protein complex.

### BN-PAGE Analysis

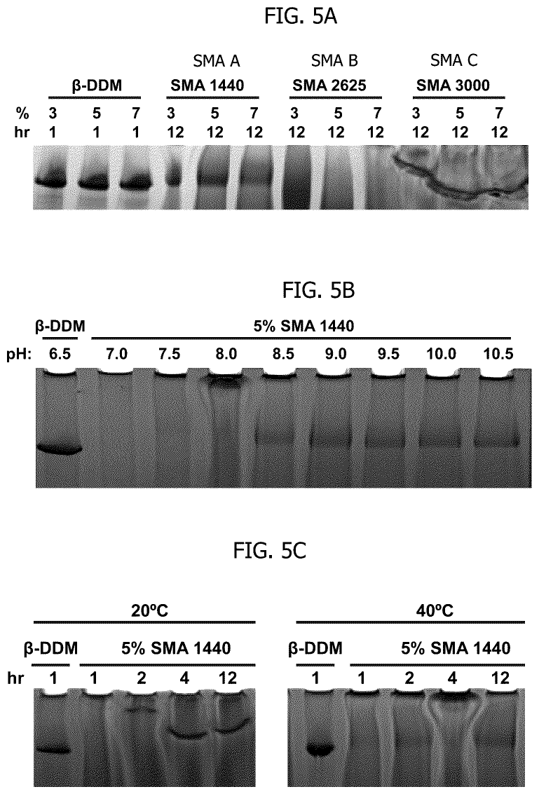

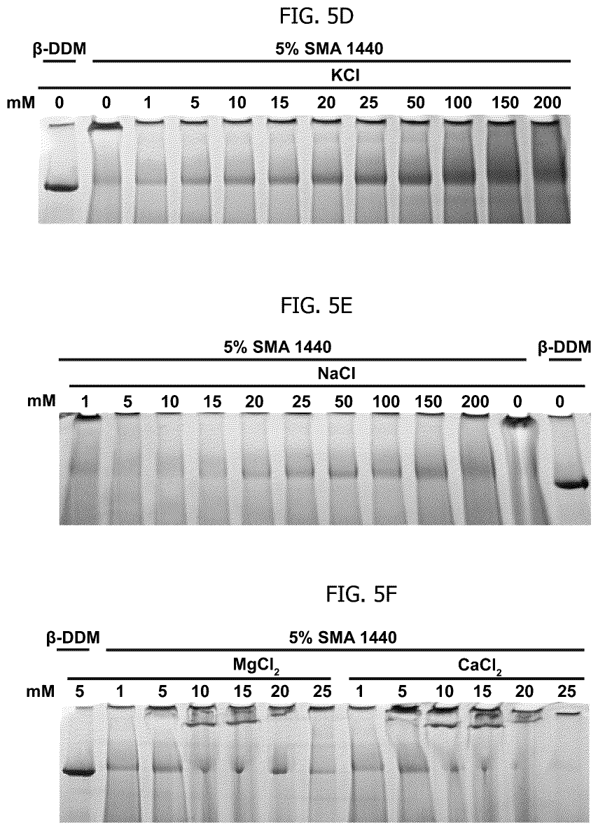

4 to 16% BN-PAGE gels (Invitrogen) were used to analyze solubilized thylakoids or isolated photosystems according to the user manual and references (Wittig et al., Blue native PAGE, Nature Protocols 2006, 1, 418) over a range of concentrations, pH, time, and cation + or cation ++ concentration. The results of the tests are shown in FIG. 5, which contains BN-PAGE gel results Parts A-F. In the BN-PAGE gels of FIG. 5, PSI trimer isolated using DDM is shown as control (0.6% DDM, B-F). Interestingly, the data herein shows that the SMA A is highly selective for only the PSI trimer.

Referring to FIG. 5, Part A, the three SMAs shown in FIG. 4 were each tested over a range of v/v concentrations −3% v/v, 5% v/v and 7% v/v after solubilization for 12 hours. The starting concentrations of neat SMA solutions obtained from Cray Valley were established gravimetrically following lyophilization. Solid content of the obtained SMA copolymers were determined to be 36.47%, 20.57% and 14.48% (w/v) for SMAs A, B, and C, respectively. Following incubation with thylakoid membranes for 12 hours at 25° C., BN-PAGE shows that SMA A is the most efficient formulation of the three tested for the solubilization of trimeric PSI out of the Te thylakoid membrane. It can also be seen that trimeric PSI extracted with SMA A shows a slight decrease in mobility by BN-PAGE, indicating a slightly larger size compared to PSI trimer isolated using DDM. Additionally, 5% of the neat SMA A solution (1.82% (w/v) total solids) was found to be the best concentration for PSI trimer extraction by SMA A from these limited trials. SMA B is unable to isolate trimeric PSI across all conditions tested. Further, SMA C did demonstrate efficacy in solubilizing a protein complex at similar size to the PSI trimer, however this result is inconclusive due to salting effect encountered in the gel when using this formulation. Overall, we did not observe effective solubilization with SMA formulations B or C, as is shown in Part A of FIG. 5. The chemical basis for this inactivity is not known, yet we have also confirmed decreased solubilization efficacy of these SMAs on protein extraction from spinach chloroplast thylakoid membranes.

Since SMA A at 5% v/v provided the best results in Part A of FIG. 5, it was used for the BN-PAGE gel tests in Parts B-F. Turning now to Part B of FIG. 5, SMA A becomes inefficient in PSI solubilization below pH=8.5. And, at pH values ranging from 9.5-10.5 there appears to be no increase in PSI trimer liberated from thylakoid membranes. As such, a pH in the range of equal to or greater than 8.5 but equal to or less than 10.5 is suitable for the solubilization. Turning now to Part C, without agitation, increasing temperature from 20° C. to 40° C. enhanced solubilization efficiency of PSI by SMA A, with more PSI trimer being isolated with increasing time from 1 to 12 hours. At 20° C., very large complexes are shown to enter the gel at 2 hours, with smaller SMALPs (still larger than trimeric PSI) being produced at 4 and 12 hours of incubation. Turning now to Parts D-F of FIG. 5, the test results show an increase in PSI extracted as concentrations of KCl (Part D) and NaCl (Part E) increase from 1 to 200 mM. However, Part F evidences a significant reduction in solubilized PSI at CaCl₂) and MgCl₂ concentrations above 10 mM.

Considering all the data from FIG. 5, the best results occurred with SMA A in 50 mM Tris-Cl (pH 9.5 at room temperature) with 125 mM KCl, incubated at 40° C. for 3 hours with agitation (shaker at 350 RPM). These conditions were used in all subsequent analyses.

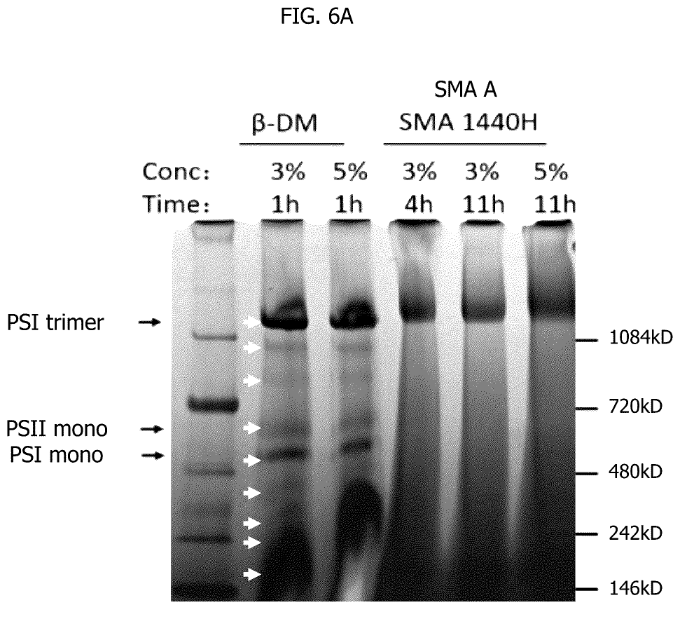

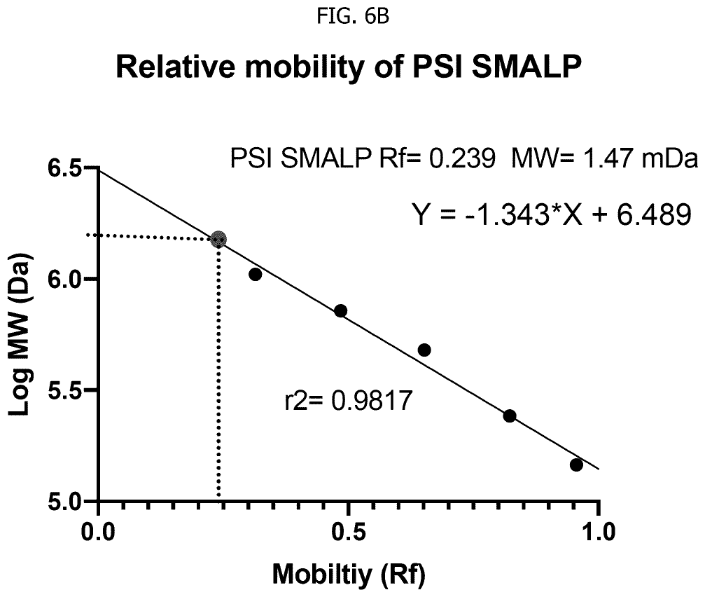

Turning now to FIG. 6, following solubilization of Te thylakoid membranes with DDM, many proteins can be seen by BN-PAGE (Part A, white arrows), whereas SMA solubilization preferentially extracts trimeric PSI alone at all concentrations and times tested (not the broad single streak in the SMA A trials). The streaking toward the bottom of the gel in the SMA lanes can be attributed to unbound SMA copolymer. The relative mobility of this PSI-SMALP reveals the size of this complex to be slightly larger than trimeric PSI-DDM, at 1.47 MDa (Part B).

### Sucrose Density Gradient Centrifugation

PSI-SMALP and PSI-DDM were first dialyzed against buffer (0.05% SMA 1440 or DDM, Tris-HCl, pH 9.0) using a 12-14 kDa molecular mass cutoff membrane (Spectrum Labs) with three buffer changes. Analytical ultracentrifugation (AUC) sedimentation velocity was performed in a Beckman Coulter ProteomeLab™ XL-I analytical ultracentrifuge using a double sector Epon, charcoal-filled centerpiece, quartz windows, and Ti50 rotor (Beckman/Coulter). Absorption measurements at 680 nm were made every minute at 30,000 rpm and 20° C., using the appropriate dialysis buffer as the reference. The buffer density and viscosity were determined by SEDNTERP to be 0.71006 g/mL, 0.99823 g/mL, and 0.001002 pascal·s respectively. Measurements were analyzed by Sedfit v.13.0b using the continuous c(s) analysis model.

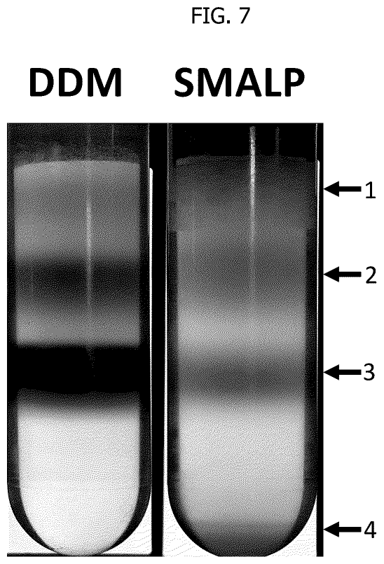

Following incubation with copolymer or detergent, insolubilized material was spun down and the supernatant was then separated using sucrose density gradient centrifugation. As shown in FIG. 7, comparing a DDM micelle and a SMALP, the sucrose gradients show distinct bands for free or liberated carotenoids (band 1), free chlorophyll (band 2) and trimeric PSI (band 3), in both DDM and SMA extracted thylakoids. In DDM preparations of cyanobacterial thylakoid membranes, band 2 also contains PSII and monomeric PSI. Interestingly, from Te, using the methods disclosed herein, trimeric PSI seems to be exclusively isolated by the SMA preparations. Further, a pellet can be seen at band 4 in FIG. 7 for the SMALP sucrose gradient, suggesting that even larger particles are being encapsulated within SMALPs. These particles may be larger thylakoid membrane fragments, or potentially multi-protein supermolecular complexes, which have long been suspected to exist within the thylakoid membrane.

### 77K Chlorophyll Fluorescence

After PSI was solubilized by SMA or DDM from Te cell membranes, measurements of chlorophyll concentration were made at 650 nm using an ultraviolet-visible light spectrophotometer, and chlorophyll concentration was standardized between both extraction methods. The extracts were then transferred into glass electron paramagnetic resonance (EPR) tubes and were slowly frozen in liquid nitrogen. Chlorophyll fluorescence spectra were obtained using a PTI Quantamaster Dual-channel fluorometer. Excitation light of 420 nm was used. The emission spectrum was measured by scanning from 550-800 nm with 0.5 nm steps, with a slit width of 1 nm. The resulting spectra was the average of 4 traces and the emission maxima was recorded.

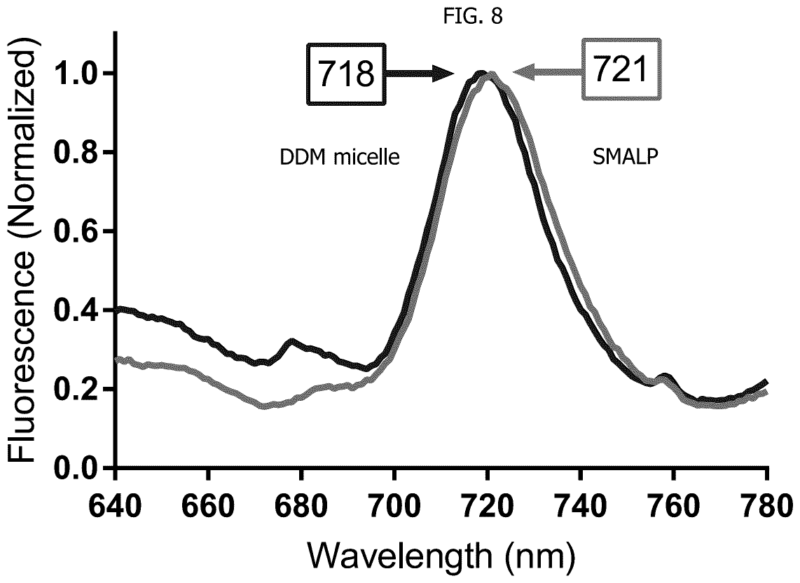

Fluorescence of Te trimeric PSI can occur at wavelengths as long as ˜730 nm in intact cells, dependent on the solvation state of the chlorophyll. It has previously been shown that as PSI goes from trimeric to monomeric form in Te, a blue shift in chlorophyll fluorescence of 3-6 nm can be seen. In addition, DDM isolation causes a blue-shift in fluorescence maximum of ˜3 nm compared to that of intact cells. Turning to FIG. 8, together, this data confirms that the 77K fluorescence emission spectra becomes more red-shifted relative to how native the setting of the protein (PSI in intact cells>DDM PSI Trimer>DDM PSI monomer). Low temperature fluorescence of band 3 from both preparations, performed in liquid nitrogen at 77 K, shows a significant 3 nm bathochromic shift in chlorophyll fluorescence for PSI-SMALP (F_{MAX}=721 nm) compared to that of PSI-DDM (F_{MAX}=718 nm). This red shift signifies a fluorescence at lower energy in the PSI-SMALP, which has been suggested to represent a more native conformation of the chlorophyll antennae structure within the reaction center. Further, it is accepted that the local environment of far-red chlorophylls are key to their emission wavelength and that a blue shift reflects more solvation and exposure to a more polar environment.

### Sodium Dodecyl Sulfate PAGE (SDS-PAGE) Analysis

For photosystem subunit profile identification of the trimeric PSI from band 3 of FIG. 7, SDS-PAGE using 10% acrylamide gel was used as described by Schägger, H., Tricine-SDS-PAGE, Nature Protocols 2006, 1, 16, and silver staining was performed using the fast stain method of Nesterenko et al., A simple modification of Blum's silver stain method allows for 30 minute detection of proteins in polyacrylamide gels, Journal of Biochemical and Biophysical Methods 1994, 28 (3), 239-242. PSI-Subunit profile for DDM extracted photosystem was confirmed using a different SDS-PAGE method, using a 18-24% gradient gel as taught by Kubota et al., Purification and characterization of photosystem I complex from Synechocystis sp. PCC 6803 by expressing histidine-tagged subunits, Biochimica et Biophysica Acta-Bioenergetics 2010, 1797 (1), 98-105.

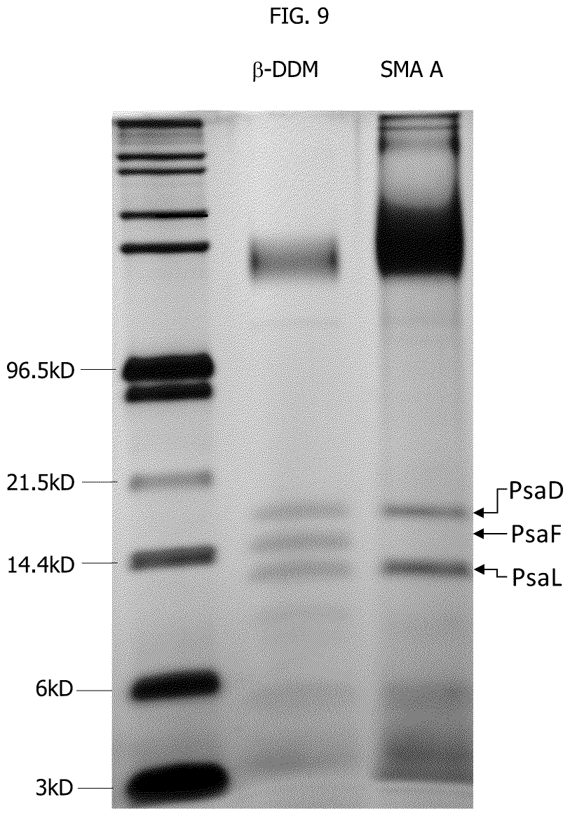

Referring now to FIG. 9, the overall subunit profile for the SMALP band 3 matched with PSI-DDM, further confirming that this band contains PSI-SMALP. Interestingly, the PsaF subunit was missing in the PSI-SMALP, while all other subunits above 3 kDa in size are present in the SMA and DDM extracted PSI trimer.

### PsaF Immunoblotting

The isolated PSI and sucrose density gradient fractions were separated by SDS-PAGE and transferred to PVDF (Immobilon, EMD Millipore, Burlington, MA). This blot was then blocked and probed with the rabbit anti-PsaB {Peptide B) antisera. The immunoblot was visualized using a GAR HRP conjugate and detected using the SuperSignal West Dura extended duration chemiluminescent substrate (Thermo Scientific, Waltham, MA).

Immunoblot analysis using a PsaF specific antibody, a-PsaF, confirms the loss of PsaF from the trimeric PSI and shows that PsaF is left behind at the top of the SMALP sucrose gradient shown in FIG. 7. The presence of this faint band suggests that PsaF has dissociated from the complex at some point during SMALP formation, and due to its small sedimentation coefficient, does not enter the sucrose gradient. This PsaF signal from the top of the sucrose gradient is diffuse due to dilution into the sucrose buffer.

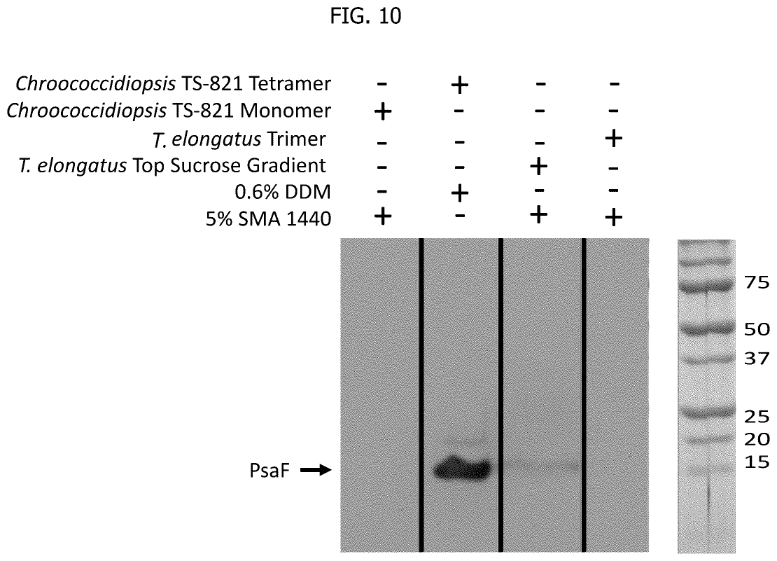

Referring now to FIG. 10, to confirm the loss of PsaF from thermophilic cyanobacterial PSI following SMA extraction, a second organism Chroococcidiopsis sp TS-821 was used and similarly probed with a-PsaF. Chroococcidiopsis sp TS-821 has been shown to produce tetrameric PSI oligomeric complexes, which have been proposed to be an intermediate conformation in the monomerization of PSI from cyanobacteria to land plants. Following SMA extraction, PSI-SMALPs isolated from Chroococcidiopsis sp TS-821 contained PSI monomers rather than tetramers, which are obtained when Chroococcidiopsis sp TS-821 thylakoids are extracted with DDM. These monomeric PSI-SMALPs also lack PsaF, whereas intact tetrameric PSI isolated using DDM retains this subunit.

P700 photooxidation and reduction by native and non-native cytochromes

Laser flash photolysis was conducted using a Joliot Type Spectrophotometer (JTS-100), equipped with an actinic LED source emitting a short excitation pulse at 630 nm and a probe beam of infrared light at 810 nm. Upon photoexcitation, P700 becomes oxidized and the absorbance of 810 nm light disappears. P700⁺ reduction rate is then monitored as the return of 810 nm absorbance. Fitting was done with a single exponential decay function in Prism 7. Constraints of plateau equal to 0 and Kobs>0 were used. 1000 iterations were used for fitting. Observed rates are plotted against molar ratio of cytochrome used.

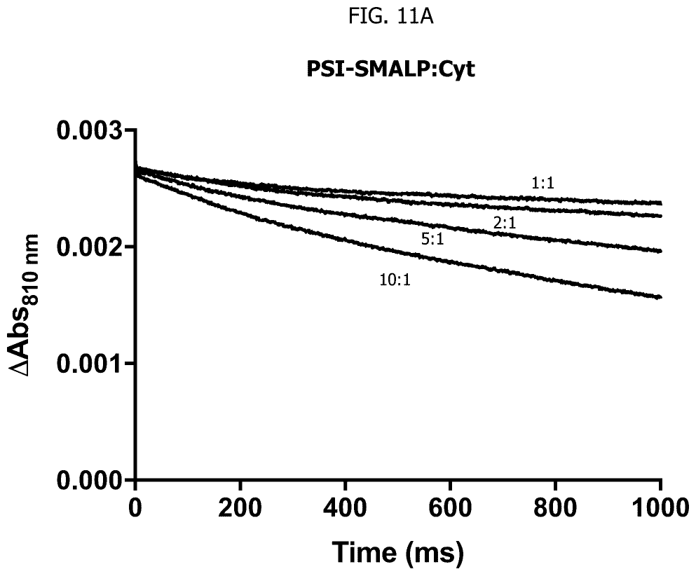

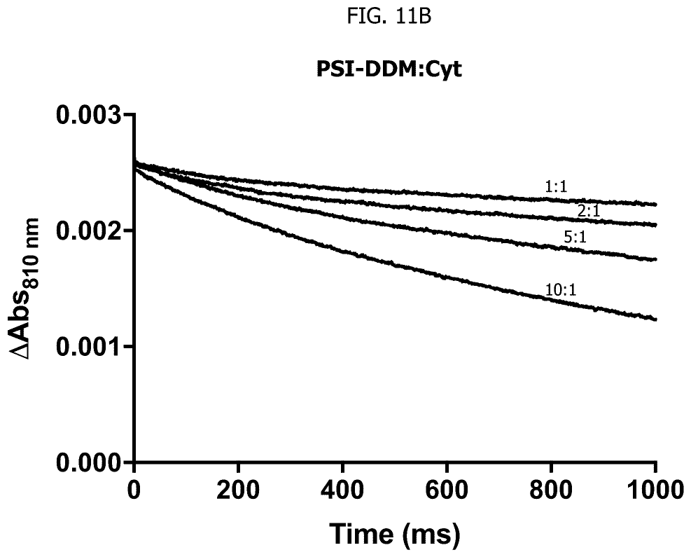

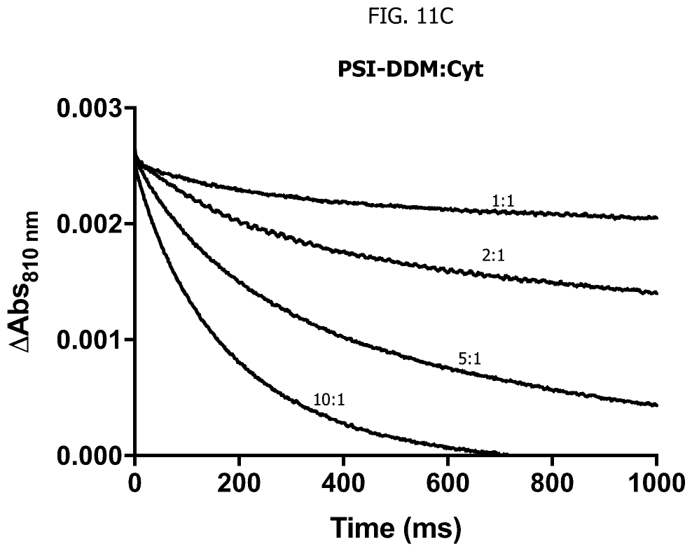

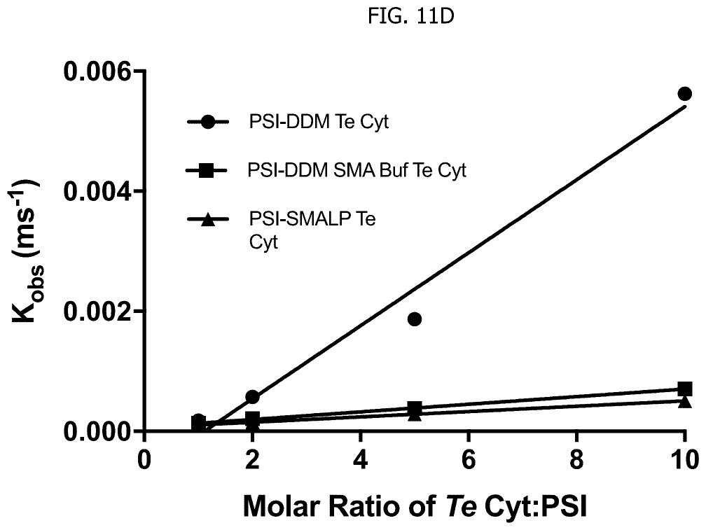

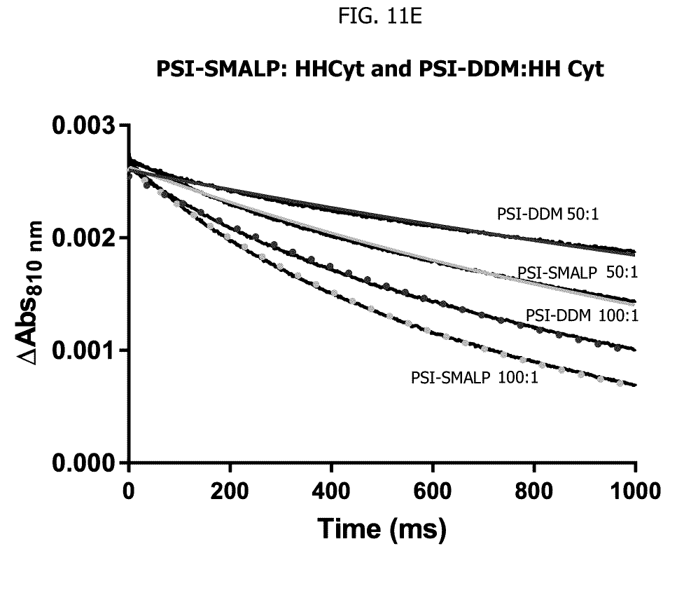

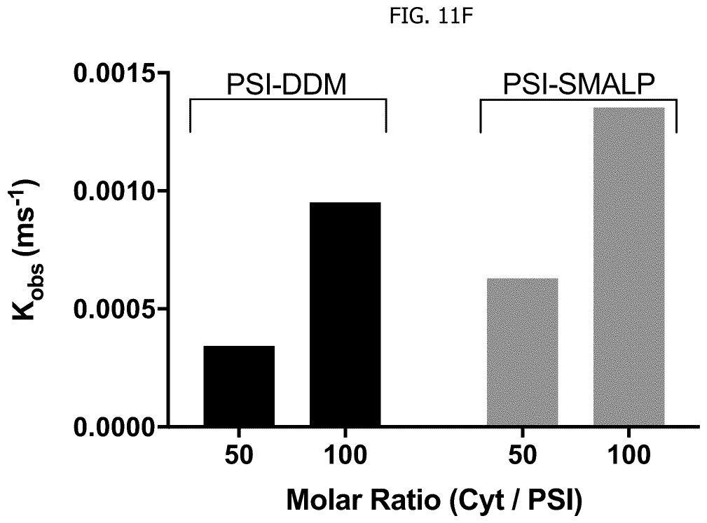

Turning now to FIG. 11, reduction kinetics of PSI-SMALP and PSI-DDM from Te using native cytochrome c₆ (cyt₆) and non-native cytochrome from horse heart (cyt_{HH}) was observed using a Joliot type spectrometer. Graphs A-D represent reduction kinetics of P700 reaction center of PSI by various ratios of native cytochrome c₆ soluble electron carrier; Cyt:PSI at 1:1, 2:1, 5:1 and 10:1. The curves represent single exponential decay traces overlaid on raw absorbance difference data. As shown in graphs A and C, significantly slower reduction kinetics for PSI-SMALP compared to PSI-DDM were observed when using cyt₆ as the electron donor when analyzed in their respective buffer systems. The buffer system for graph A was PSI-SMALP in 50 mM Tris-Cl with 150 mM KCl at pH=9.5 (“SMA buffer”). The buffer system for graph B was 50 mM Tris-Cl and 125 mM KCl at pH=9.5 (room temperature) (“buffer S”). The buffer for Graph C was 50 mM MES-NaOH, pH=6.5, 5 mM CaCl₂, and 10 mM MgCl₂ (“buffer A”). When both PSI-SMALP and PSI-DDM are analyzed in buffer S, PSI reduction occurs at comparable rates for both particles.

Graph D shows observed reduction rate constants from single exponential decay curves plotted against molar ratio of cytochrome c₆ for PSI-DDM in DDM buffer, PSI-DDM in SMA buffer, and for PSI-SMALP in SMA buffer.

Graph E is a P700 reduction curve for PSI-DDM and PSI-SMALP using horse heart cytochrome at 50:1 (solid lines) and 100:1 (dotted lines) ratios of Cyt/PSI. For both the solid lines and the dotted lines, PSI-DDM is above the PSI-SMALP curve. Graph F is observed P700 reduction rates of PSI-DDM and PSI-SMALP with horse heart cytochrome. Interestingly, in graphs E and F, when cyt_{HH} is used, the reduction rate of PSI-SMALP exceeds that of PSI-DDM. The ability for PSI-SMALP to become both photooxidized and reduced by cyt₆ and cyt_{HH} indicates that the core of the PSI complex remains intact and the electron transfer chain within the reaction center remains functional, despite the loss of PsaF.

The rate of P700⁺ reduction seen in FIG. 11 also suggests that the iron sulfur cluster containing subunit PsaC (Specifically F_{A} and F_{B}) is intact and functional. Without these FeS clusters, charge recombination to reduce P700⁺ would dominate. This process has been previously shown to occur on the timescale of 750 μs, which would be shown via ultrafast reduction of P700⁺. FIG. 11 clearly shows reduction of P700⁺ occurring at the millisecond timescale, indicative of externally facilitated reduction of the reaction center. The stromal subunits (PsaC, D and E) have also been shown to be very tightly associated to the PSI core complex, requiring treatment with 3.5-6.8 M chaotropic agents (depending on strength of chaotrope) to dissociate these subunits. Therefore, though it is difficult to resolve these small molecular weight subunits by SDS-PAGE (FIG. 9), we are confident these subunits are retained in the PSI-SMALP.

Sedimentation Velocity using Analytical Ultracentrifugation

PSI-SMALP and PSI-DDM were first dialyzed against buffer (0.05% SMA 1440 or DDM, Tris-HCl, pH 9.0) using a 12-14 kDa molecular mass cutoff membrane (Spectrum Labs) with three buffer changes. Analytical ultracentrifugation (AUC) sedimentation velocity was performed in a Beckman Coulter ProteomeLab™ XL-I analytical ultracentrifuge using a double sector Epon, charcoal-filled centerpiece, quartz windows, and Ti50 rotor (Beckman/Coulter). Absorption measurements at 680 nm were made every minute at 30,000 rpm and 20° C., using the appropriate dialysis buffer as the reference. The buffer density and viscosity were determined by SEDNTERP to be 0.71006 g/mL, 0.99823 g/mL, and 0.001002 pascal·s respectively. Measurements were analyzed by Sedfit v.13.0b using the continuous c(s) analysis model from Schuck, P., Size-distribution analysis of macromolecules by sedimentation velocity ultracentrifugation and lamm equation modeling, Biophys J 2000, 78 (3), 1606-19.

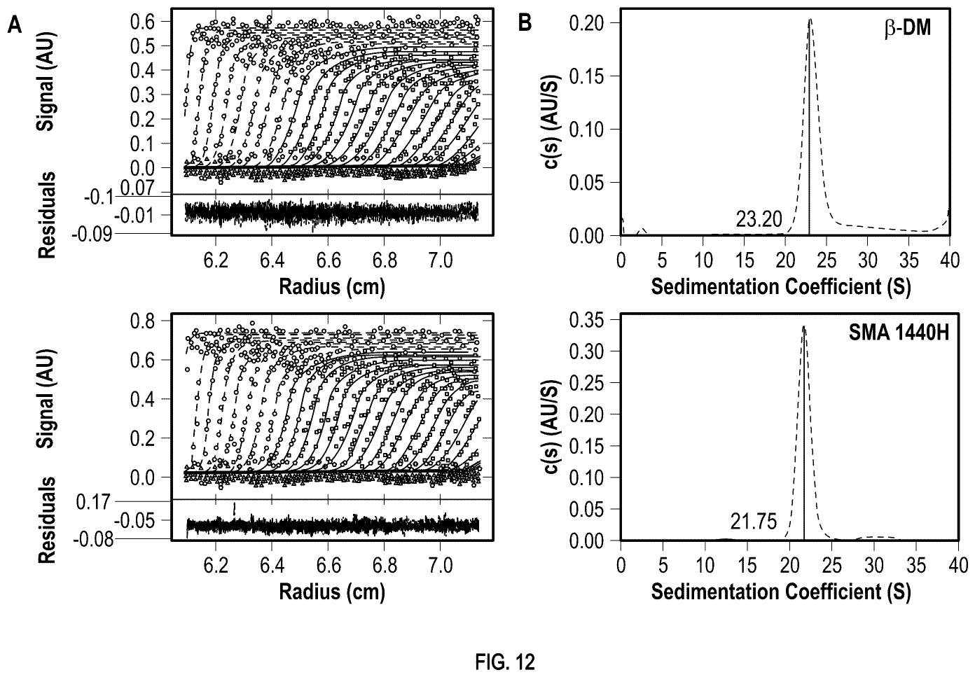

Turning now to FIG. 12, the difference in sedimentation coefficient between PSI-SMALP and PSI-DDM was determined by tracking particle movement by monitoring chlorophyll absorbance at 680 nm. From sedimentation velocities for PSI-DDM (Graph A, top) and PSI-SMALP (Graph A, bottom), sedimentation coefficients of 23.20 and 21.75 svedbergs for PSI-DDM (Graph B, top) and PSI-SMALP (Graph B, bottom), respectively, were determined. These data imply that the PSI-SMALP is either less dense or experiences more resistance while migrating through the chamber. The former possibility is in line with previous studies that report increased lipid to protein ratios in SMALPs, which would cause a decrease in particle density. The latter may be caused by extended geometry, or larger overall particle size. Further investigation is needed to discern which of these (or both) is the case for PSI-SMALP, but these sedimentation coefficients correlate well previously reported values for trimeric PSI and differ from monomeric, dimeric and tetrameric forms. Further, the AUC results in FIG. 12 suggest the protein preparations are clean, containing only trimeric PSI particles.

### Pump-probe Femtosecond Spectroscopy

Time-resolved difference absorption spectra ΔA(λ,t) were measured by a pump-probe method according to Cherepanov et al., Mechanism of adiabatic primary electron transfer in photosystem I: Femtosecond spectroscopy upon excitation of reaction center in the far-red edge of the QY band, Biochimica et Biophysica Acta-Bioenergetics. 2017; 1858 (11): 895-905. Excitation pulses were centered at wavelengths of 740 nm and 670 nm. In the experiments with excitation at 740 nm, the pulses had energy of 100 nJ and a duration of 26 fs. In the case of excitation pulses at 670 nm, the pulse spectrum was filtered by the SLM modulator so that spectral components redder than 680 nm were absent. In this case, the excitation pulse duration was 34 fs, and the energy was 5 nJ. The excitation pulses were focused in a 0.5 mm thick cuvette with thin quartz glasses (150 μm thick) into a spot with a diameter of 180 μm. A pulse of white continuum focused in a spot of 120 μm diameter was used as a probe pulse. Polarizations of the pump and probe pulses were oriented by a magic angle of 54.7°. The pulse repetition rate was 100 Hz. The sample was circulated by a micropump through a cuvette at a rate sufficient to completely replace the exposed volume between the pulses. In this case, the samples were cooled to +6° C. The zero time delay between the pump pulse and corresponding spectral component λ of the probe pulse was corrected by a method described by Shelaev et al., Femtosecond primary charge separation in Synechocystis sp. PCC 6803 photosystem I., Biochimica et Biophysica Acta-Bioenergetics. 2010; 1797 (8): 1410-20. The difference absorption spectra ΔA(λ,t)=A(λ,t)−A₀(k) obtained by the pump-probe femtosecond laser photolysis are the difference of between the spectrum of the PS1 A(λ,t) at the time delay t and the absorption spectrum of PSI without excitation A₀(k).

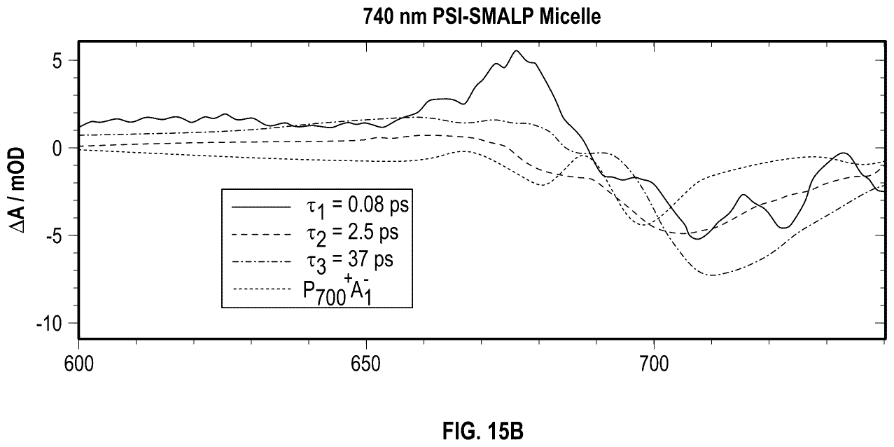

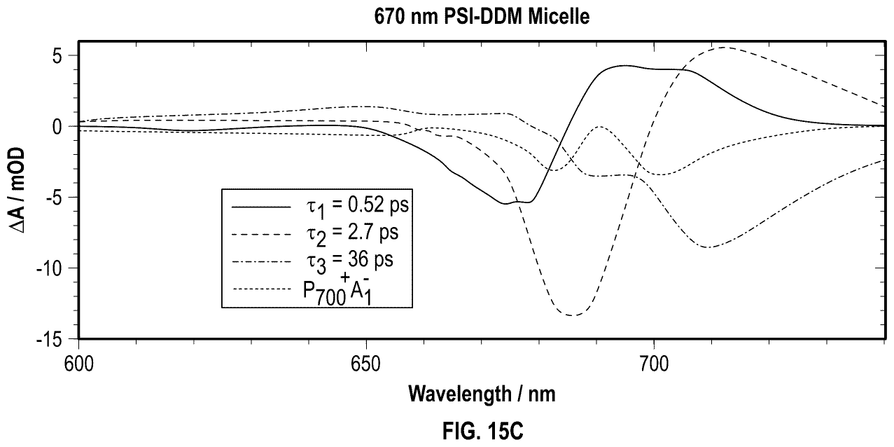

FIG. 15 shows the results of the global exponential deconvolution of the spectral dynamics of PSI-DDM preparations from T. elongatus upon direct excitation of LWC by a pulse at 740 nm. In this regard, the positive amplitude of the spectrum corresponds to an increase in bleaching in this optical region, and the negative one—to an increase of the optical absorption. Under long-wavelength excitation, the optical dynamics of PSI revealed fast energy redistribution processes between the antenna pigments with characteristic times τ₁=80 fs and τ₂=2.4 ps. With reference to FIG. 15A, these components have small amplitudes and a similar form: a decrease of bleaching at 705 nm and a slight decrease of absorption at 680 nm. The main spectral changes occurred with a characteristic time τ₃=36 ps, which characterizes the process of energy transfer from the LWC forms in antenna to the cofactors in RC. Note that because the characteristic time of electron transfer from chlorophyll A₀ to phylloquinone A₁ is ˜25 μs, the kinetics of the intermediate reduction of chlorophyll A₀ remains unresolved. Consequently, spectral changes in the absorption maximum of A₀ (685 nm) at τ≥36 μs are absent; the spectrum at the maximal delay t_{d}=500 μs reflects the spectrum of the ion-radical pair P₇₀₀⁺A₁⁻.

Referring now to FIG. 15B, the exponential deconvolution of the spectral dynamics in PSI-SMALP complexes excited by a similar long-wave pulse (740 nm) are shown. Qualitatively, the optical dynamics in these preparations resembled the dynamics of PSI-DDM samples in FIG. 15A; however, several significant differences were revealed. First, the amplitude of bleaching dynamics at 680 nm in the ultrafast τ₁=80 fs component is substantially increased. Secondly, the fast component τ₂=2.5 ps in SMA-PSI preparations has an approximately doubled amplitude relative to PSI-DDM and reveals an additional minimum at 685 nm, which can be attributed to the chlorophyll A₀ absorption. Thirdly, the amplitude of the slow component τ₃=37 μs is strongly reduced relative to the final spectrum of the radical ion pair P700⁺A₁⁻. All these features together indicate that in PSI-SMALP preparation, a fast energy transfer from the LWC forms to the RC is observed.

Referring now to FIG. 15C, the deconvolution of the spectral dynamics of PSI excited by pulses at 670 nm, which required three exponential components with the characteristic times τ₁=0.52 ps, τ₂=2.7 ps and τ₃=36 ps, respectively, as well as the final differential spectrum of the ion-radical pair P₇₀₀⁺A₁⁻ (offset) are shown. Components with τ₁=0.52 ps and τ₂=2.7 μs characterize the process of energy transfer from excited chlorophyll molecules with an absorption maximum at ˜670 nm to longer wavelengths with a maximum at ˜710 nm. The slowest component (τ₃=36 ps) describes the process of energy transfer from the LWC to the PSI RC and the subsequent charge separation process with the formation of the final spectrum of the ion-radical pair P₇₀₀⁺A₁⁻. Notably, the relative amplitude of the component τ₃=36 ps in PSI preparations excited by pulses at 670 nm, is smaller than the amplitude of the analogous component observed when the long-wavelength forms of chlorophyll were excited directly by pulses at 740 nm (FIG. 15A). Apparently, this difference is due to the fact that when PSI is excited by 670 nm pulses, a significant part of the energy flows from the light-harvesting antenna directly to the RC, bypassing the long-wave forms of chlorophyll. The relative contributions of both energy transfer channels can be estimated by comparing the amplitude of the LWC bleaching in the τ₃=36 ps component at 710 nm (ΔA_{LWC}) with the amplitude of P₇₀₀ bleaching in the final P₇₀₀⁺A₁⁻ spectrum at 700 nm (ΔA_{P700}). Upon excitation of the DM-PSI preparation by pulses at 740 nm, all energy is localized on the LWC forms, and the ratio ΔA_{LWC}/ΔA_{P700}=3.0. When PSI is excited by pulses at 670 nm, the ratio ΔA_{LWC}/ΔA_{P700}=2.5, so 17% of the energy flows directly into the RC, and 83% is redistributed to the long-wavelength forms of chlorophyll. It is noteworthy that in the SMA-PSI samples excited by 740 nm pulses, the ratio ΔA_{LWC}/ΔΔP₇₀₀=1.7, hence ˜45% of the energy gets the RC with ultrafast femtosecond kinetics on the time scale of 0.1 μs.

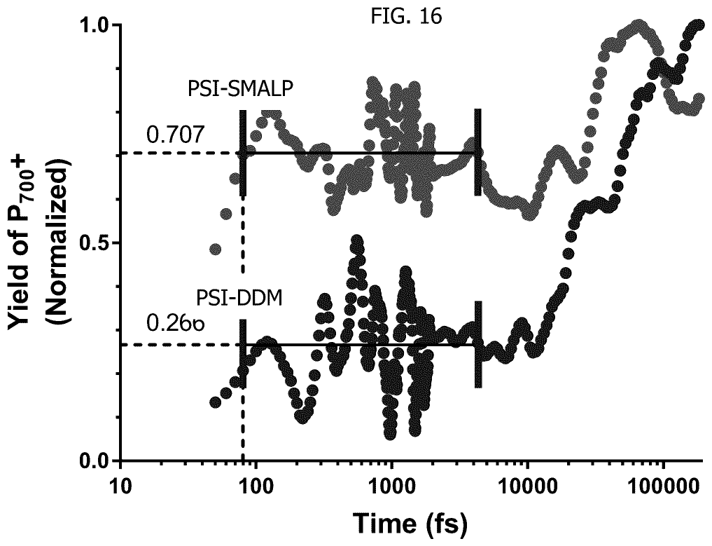

Referring now to FIG. 16, the comparison of the two samples demonstrates that in the PSI-DDM preparation, formation of the P₇₀₀⁺ electrochromic signature takes place to a great extent on the time scale of 40 μs, whereas in the PSI-SMALP preparation an ultrafast (≤0.1 μs) formation of the cationic state P₇₀₀⁺ takes place in a large part of the complexes.

The data shown in FIGS. 15 and 16 allow us to conclude that the formation of the P₇₀₀⁺ cation is characterized by a red electrochromic shift of the absorption band of the nearest second chlorophyll pair Chl2A/Chl2B with an absorption maximum of about 685 nm. The main difference with the PSI-DDM samples are an increase in the magnitude of the ultrafast 80 fs component and the reciprocal decrease in the magnitude of the slow 40 ps component attributed to the energy transfer from the LWC to RC. FIG. 15C shows the excitation migration from pigments absorbing at 670 nm to the LWC in the PSI-DDM complexes excited at 670 nm. The excitation migration looks as a consecutive process, where the energy is transferred step-by-step from the high-energy to low-energy chlorophyll forms. The charge separation occurs predominantly at 40 ps, similar to the case of direct far-red excitation at 740 nm.

The data clearly demonstrate that the use of DDM detergent significantly affects the rate and efficiency of energy transfer processes initiated by the excitation of long-wavelength forms of chlorophyll in PSI. In PSI-SMALP complexes, an ultrafast formation of a cation of the special chlorophyll pair P₇₀₀⁺ was observed in the time interval of 0.1 ps. This means that the rate constant of the primary charge separation m1 is as high as 10 μs⁻¹. In these preparations excited in the far-red region of the antenna (740 nm), about 45% of the energy reached the RC with a characteristic time of about 100 fs. In about 55% of the complexes, the excitation remained localized on the long-wavelength forms of chlorophyll and the transfer of excitation energy to the RC occurred with the characteristic time of 36 ps.

The PSI absorption spectrum in the red edge demonstrated an exponential dependence (known as the Urbach rule), which was attributed to the effect of strong electronic coupling between the excited P₇₀₀* and the charge-separated states P₇₀₀⁺A_{0A}⁻ and P₇₀₀⁺A_{0B}⁻ in both branches of redox-cofactors. Due to the presence of long-wavelength chlorophyll C-719 in the antenna of T. elongatus, the far-red pulse (740 nm) excited almost in equal proportions both the LWC in antenna and the dimer P₇₀₀ in RC of the PSI-SMALP complex.

### Working Example 2

A plurality of photo-electrical energy generating devices were made and tested to determine the exhibited photovoltage and photocurrent of the devices when amphiphilic co-polymer lipid particles are included in the device. First, PSI-SMALP and PSI-DDM micelles were formed according to Working Example 1 above. After sucrose density ultracentrifugation, both the PSI-SMALP and PSI-DDM micelle samples were concentrated using Millipore Amicon centrifugal concentrators, with numerous spins at 3,500×g for 10-15 minutes. The samples were concentrated three times, being diluted with buffer (SMA buffer for the SMALPs and buffer A for the DDM) twice to remove the sucrose.

The chlorophyll content was measured as set forth in Working Example 1 and adjusted to yield the same P700 levels based on equivalent P700 photobleaching levels using a JTS-100 LED pulse/probe spectrometer. The samples were normalized to a 4:5 ratio to ensure equal loading of P700 reaction centers (e.g., one reaction center per PSI monomer).

Each PSI-SMALP and PSI-DDM solution, prior to drop-casting, was diluted 4-fold into Tris-Cl buffer, pH 9.5 at room temperature to decrease the salt content. The final chlorophyll concentration of these solutions were in a range of 0.2 to 0.3 mg/mL. Specifically, the PSI-SMALP solution had a chlorophyll concentration of 0.25 mg/mL and the PSI-DDM had a chlorophyll concentration of 0.3 mg/mL.

A plurality of p-type silicon electrodes having a native oxide surface were provided. The surface of each p-type silicon electrode had a contained area of 0.24 cm². To this contained area, 75 μL of either the PSI-SMALP solution or the PSI-DDM solution was drop-cast thereon. Each drop-cast solution was dried under vacuum for 1-2 hours. Thereafter, on the dry drop-cast layer, 75 μL of TiO₂ nanoparticles in suspension were drop-cast and then dried under vacuum for 1-2 hours. An indium-doped tine oxide plastic electrode was positioned with the conductive side facing the drop-cast layers. The layers were pressed firmly together between transparent glass outermost layers and were clamped together, thereby having the structure set forth in FIG. 17. The clamped, layered structure was set to cure for about 7-12 hours.

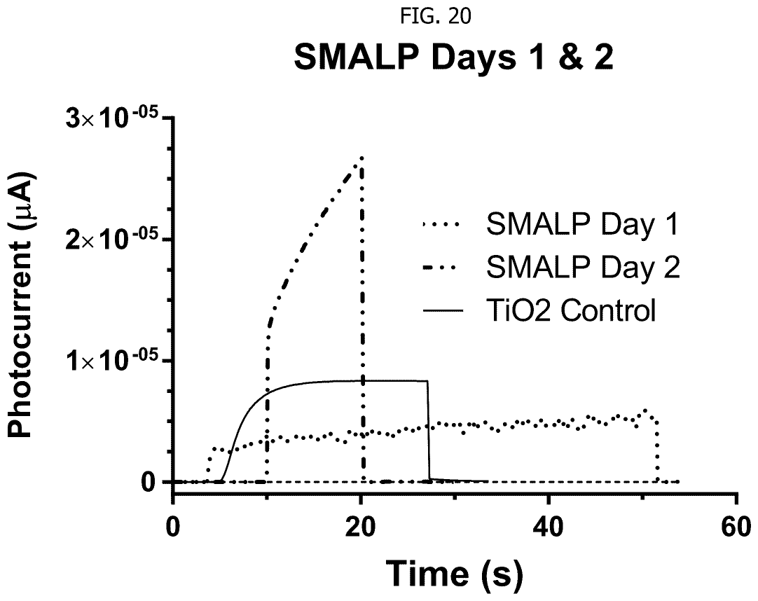

The plurality of devices were masked such that a photoactive area of about 0.24 cm² was available for each device. The photocurrent for each device was normalized to current density as amp/cm² to enable direct comparisons of the devices. A control cell having only a titanium dioxide semiconductor layers was prepared and is noted as TiO₂ control in the tables below. “Spinach” data for PSI solubilized by detergent from Dervishogullari et al., Langmuir, 2018, 34, 15658-664 was included for comparative purposes. The devices containing PSI-detergent micelles from Spinach had a photocurrent density of 33 μA/cm², a photovoltage of 210 mV, and a wattage of 0.114 W. The control cell exhibited a fast spike to a plateau, with a maximum photocurrent of 33.8 μA/cm², see FIG. 20.

TABLE 1
Photocurrent

| | | | | Illumination Time |
|---|---|---|---|---|
| Treatment | Photocurrent Density | | Day | (seconds) |
| Spinach | 33 | μA/cm² | n/a | |
| PSI-SMALP | 25.3 | μA/cm² | 1 | |
| PSI-DDM | 71.7 | μA/cm² | 1 | |
| Silicon PV | 35 | mA/cm² | | |
| PSI-SMALP | 391 | μA/cm² | 2 | 300 |
| PSI-DDM | 321 | μA/cm² | 1 | 300 |
| PSI-DDM | 497 | μA/cm² | 1 | 1000 |
| PSI-DDM | 573 | μA/cm² | 1 | 1600 |
| TiO₂ Control | 56 | μA/cm² | 1 | |

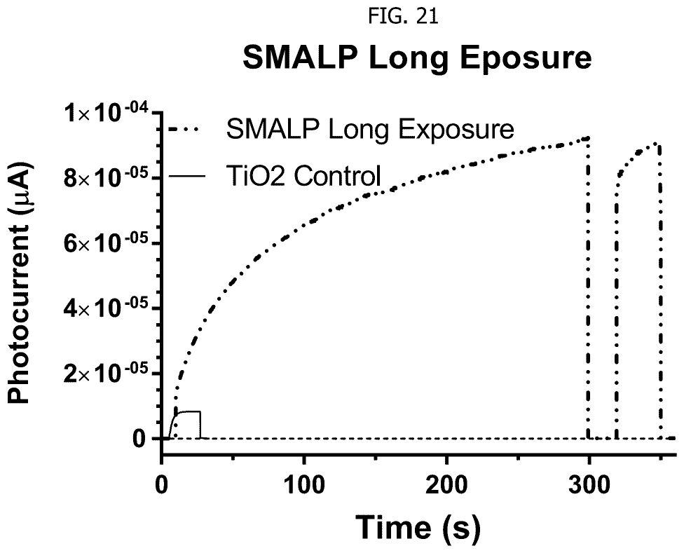

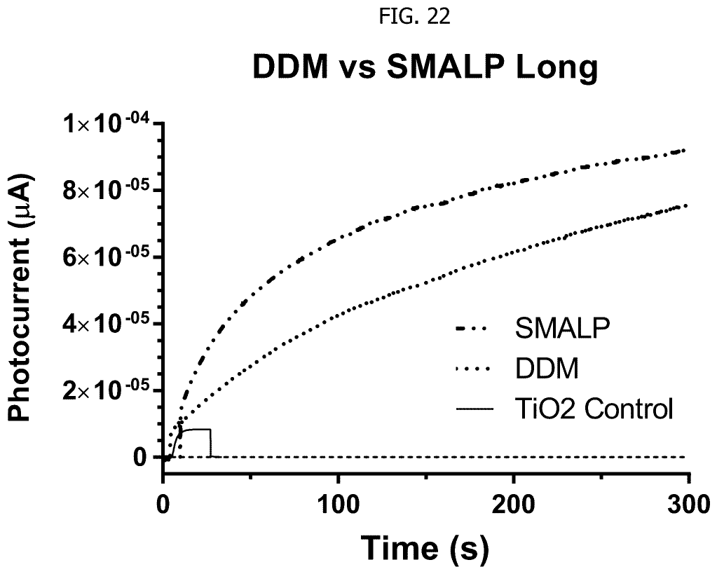

The presence of the PSI-SMALP and the PSI-DDM in the devices, evidence a rise in photocurrent over time as seen by the data in Table 1 and FIGS. 20-23. The PSI-SMALP devices had a photocurrent density that was almost 22% higher than the PSI-DDM at 300 seconds (i.e., the long exposure).

TABLE 2
Photovoltage

| Treatment | Photovoltage | Day |
|---|---|---|
| Spinach | 210 mV | n/a |
| PSI-SMALP | 221 mV | 1 |
| PSI-DDM | 112 mV | 1 |
| PSI-SMALP | 187 mV | 2 |

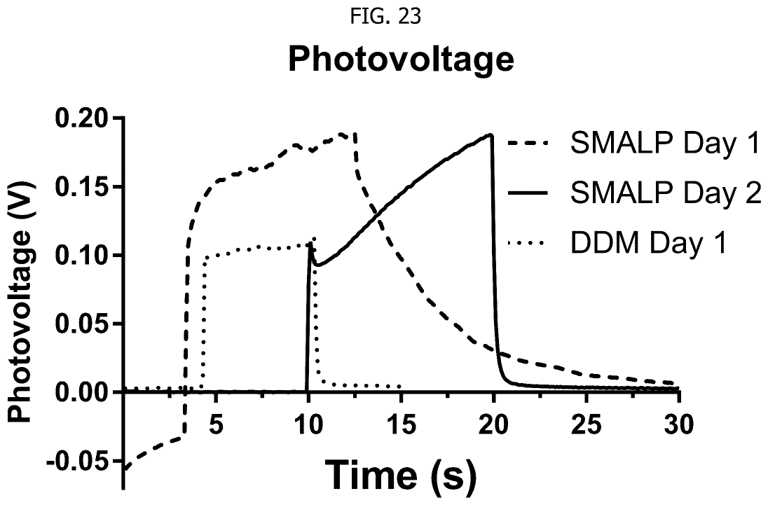

The PSI-SMALP devices had a photovoltage about twice that of the PSI-DDM containing devices. Data is also shown in graph form in FIG. 23.

TABLE 3
Power

| Treatment | Wattage |
|---|---|
| Spinach | 0.114 W |
| PSI-SMALP | 1.43 W |
| PSI-DDM | 1.06 W |
| Silicon PV | 375 W |

Even the wattage of the PSI-SMALP containing device was higher than the PSI-DDM containing device. As a whole, the PSI-SMALP containing device outperformed the PSI-DDM containing device in all aspects.

The data evidences that SMA A, an SMA having maleic acid is esterified with an alkoxy functional group, was the most efficient amphiphilic copolymer for the extraction of trimeric PSI-SMALP from Te. SMA A also had the shortest co-polymer length and the least amount of styrene in the styrene to maleic acid ratio, about 1:5. Interestingly, this solubilization method selectively lost PsaF, a single subunit that binds to the outer edge of the complex, from the trimeric PSI. The trimeric PSI has a size of about 1.5 MDa (more specifically 1.47 MDa) and is the largest protein to be isolated using any type of non-detergent solubilization. The data suggests that smaller copolymer fragments, with low S:MA ratio and increased hydrophobicity through ester formation with alkoxy groups will be able to perform reaction center isolation from highly saturated, galactolipid rich membrane systems.

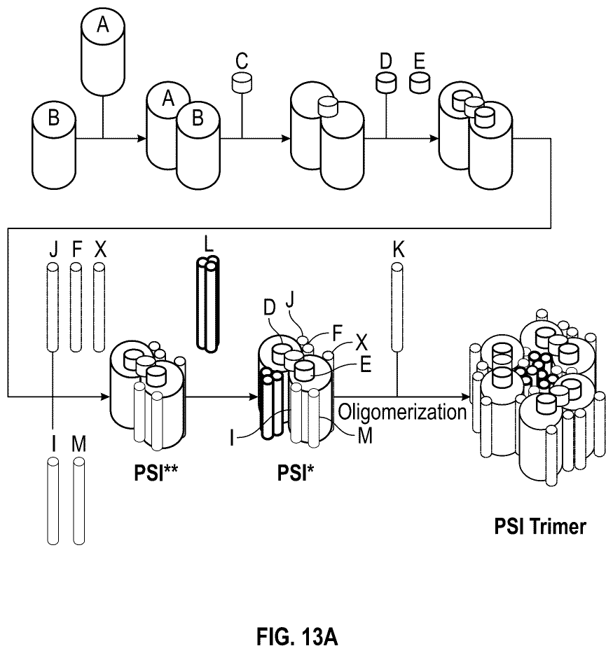

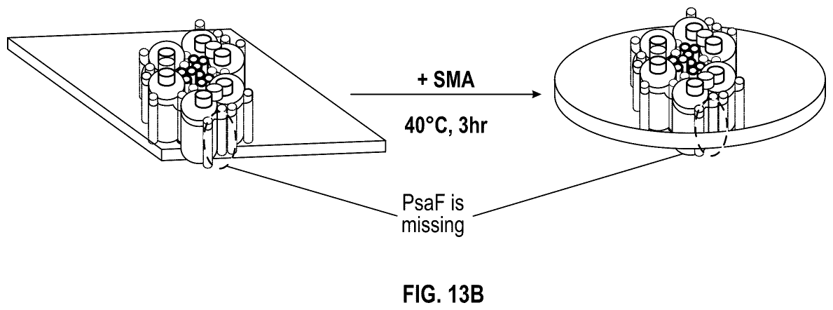

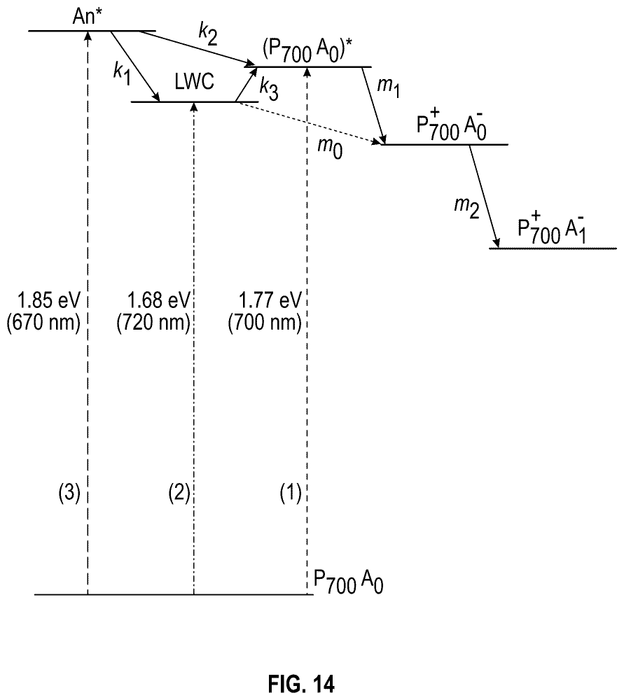

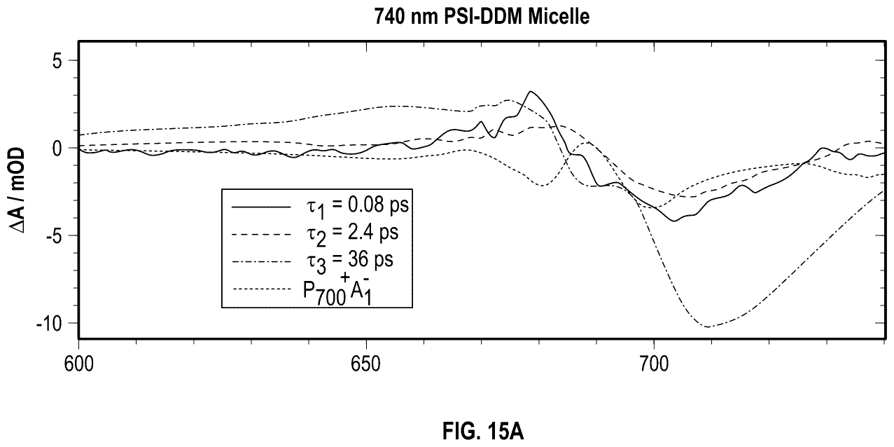

FIG. 13A is a schematic model of a proposed order of assembly for PSI subunits. And, upon solubilization with SMA A at 40° C. for at least 3 hours, as shown in FIG. 13B PSI-SMALPs are formed. Asterisks denote short-lived intermediate complexes. These particles lack PsaF subunit normally associated to the outer edge of the protein complex as discussed above. However, the decrease in reduction kinetics for PSI-SMALP and PSI-DDM are attributed to elevated pH and a lack of divalent ions, not the absence of the PsaF subunit.

The key difference between SMA and DDM extractions with regard to this structure/function relationship deals with the preservation of native lipids surrounding and throughout the membrane protein complexes. Decreased migration of PSI-SMALP into BN-PAGE suggest this particle is larger in size than PSI-DDM. Further, decreased sedimentation of PSI-SMALP compared to PSI-DDM suggests PSI-SMALPs either contain more lipids, resulting in a less dense complex, and/or exhibit a larger or more extended shape than DDM extracted PSI. This finding agrees with the overall consensus in the field that proteins embedded within SMALPs are disc shaped, retaining an annulus of native lipids.

It should be noted that the embodiments are not limited in their application or use to the details of construction and arrangement of parts and steps illustrated in the drawings and description. Features of the illustrative embodiments, constructions, and variants may be implemented or incorporated in other embodiments, constructions, variants, and modifications, and may be practiced or carried out in various ways. Furthermore, unless otherwise indicated, the terms and expressions employed herein have been chosen for the purpose of describing the illustrative embodiments of the present invention for the convenience of the reader and are not for the purpose of limiting the invention.

Having described the invention in detail and by reference to preferred embodiments thereof, it will be apparent that modifications and variations are possible without departing from the scope of the invention which is defined in the appended claims.

What is claimed is:

1. An amphiphilic co-polymer lipid particle comprising:
a core comprising a chlorophyll pigment-protein complex or a bacteriochlorophyll pigment-protein complex within an annulus of membrane lipids; and
an outermost layer of amphiphilic co-polymer surrounding an outermost surface of the membrane lipids;
wherein the amphiphilic co-polymer is selected from the group consisting of styrene maleic acid, diisobutylene maleic acid, styrene maleimide and combinations thereof.

2. The amphiphilic co-polymer lipid particle of claim 1, wherein the chlorophyll pigment-protein complex or bacteriochlorophyll pigment-protein complex are from a chloroplast of a plant or algae, or from a photosynthetic bacterium or a cyanobacteria.

3. The amphiphilic co-polymer lipid particle of claim 2, wherein the chlorophyll pigment-protein complex or bacteriochlorophyll pigment-protein complex comprise a photosystem I complex, a photosystem II complex, or combinations thereof.

4. The amphiphilic co-polymer lipid particle of claim 1, wherein when the photosystem I complex is present, the particles are disc-shaped nanoparticles.

5. The amphiphilic co-polymer lipid particle of claim 1, wherein the amphiphilic co-polymer has a hydrophobic portion selected from styrene or diisobutylene and a hydrophilic portion selected from maleic acid, carboxyl amide, or maleimide.

6. The amphiphilic co-polymer lipid particle of claim 5, wherein the amphiphilic co-polymer is styrene maleic acid.

7. The amphiphilic co-polymer lipid particle of claim 6, wherein the maleic acid is esterified with an alkoxy functional group.

8. The amphiphilic co-polymer lipid particle of claim 7, wherein the alkoxy functional group is selected from the group consisting of methoxy, ethoxy, propoxy, butoxy, pentoxy, hexoxy, and combinations thereof.

9. A method for making amphiphilic co-polymer lipid particles, the method comprising:
isolating photosynthetic membrane to form isolated photosynthetic membrane;
adjusting the chlorophyll concentration of the isolated photosynthetic membrane; and
solubilizing the isolated photosynthetic membranes in an amphiphilic co-polymer selected from the group consisting of styrene maleic acid, diisobutylene maleic acid, styrene maleimide, and combinations thereof for a preselected time period that allows amphiphilic copolymer lipid particles to form.

10. The method of claim 9, wherein the time period is 1 hour to 12 hours.

11. The method of claim 9, wherein the amphiphilic co-polymer is styrene maleic acid.

12. The method of claim 11, wherein the maleic acid is esterified with an alkoxy functional group.

13. The method of claim 12, wherein the alkoxy functional group is selected from the group consisting of methoxy, ethoxy, propoxy, butoxy, pentoxy, hexoxy, and combinations thereof.

14. The method of claim 9, wherein solubilizing the isolated photosynthetic membrane includes maintaining the pH in the range of equal to or greater than 8.5 but equal to or less than 10.5.

15. The method of claim 14, wherein solubilizing the isolated photosynthetic membrane includes adjusting a solubilizing temperature to a range of about 4° C. to 60° C.

16. The method of claim 9, wherein solubilizing the isolated photosynthetic membrane includes the addition of 25 mM to 500 mM of monovalent cations.

17. The method of claim 9, wherein adjusting the chlorophyll concentration comprises normalizing the chlorophyll concentration to a value within a range of 0.5 mg/mL to 1.5 mg/mL.
